(19) United States
(12) Patent Application Publication
(10) Pub. No.: US 2010/0225419 A1
(43) Pub. Date: Sep. 9, 2010

(54) PASSIVE SWITCHED-CAPACITOR FILTERS

(75) Inventors: Chengzhi Pan, San Diego, CA (US); Joseph Burke, Glenview, IL (US); Russell Fagg, San Diego, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/400,711

(22) Filed: Mar. 9, 2009

(51) Int. Cl. H03H 7/00

(52) U.S. Cl. 333/174

(57) ABSTRACT

A passive switched-capacitor (PSC) filter includes (i) an array of capacitors that can store and share electrical charge and (ii) an array of switches that can couple the capacitors to a summing node. Each switch couples an associated capacitor to the summing node when enabled. Each capacitor stores a voltage value from the summing node when selected for charging and shares electrical charge with other capacitors via the summing node when selected for charge sharing. The PSC filter may include multiple sections for multiple filter taps. Each section includes one or more capacitors of equal size determined based on a corresponding filter coefficient. The capacitors in each section may be sequentially selected for charging with an input or output signal, one capacitor in each clock cycle. In each clock cycle, one capacitor in each section may be selected for charge sharing to generate the output signal.

### BACKGROUND

I. Field

The present disclosure relates generally to electronics, and more specifically to filters.

II. Background

Filters are commonly used to filter signals to pass desired signal components and to attenuate undesired signal components. Filters are widely used for various applications such as communication, computing, networking, consumer electronics, etc. For example, in a wireless communication device such as a cellular phone, filters may be used to filter a received signal to pass a desired signal on a specific frequency channel and to attenuate out-of-band signals and noise. For many applications, filters that occupy small area and consume low power are highly desirable.

### SUMMARY

Passive switched-capacitor (PSC) filters that may occupy smaller area and consume less power are described herein. In one design, a PSC filter includes (i) a plurality of capacitors that can store and share electrical charge and (ii) a plurality of switches that can couple the plurality of capacitors to a summing node. Each switch couples an associated capacitor to the summing node when enabled and decouples the associated capacitor from the summing node when disabled. Each capacitor stores a voltage value from the summing node when selected for charging and shares electrical charge with other capacitors via the summing node when selected for charge sharing.

The PSC filter may further include an input switch, a reset switch, an output switch, and an input capacitor. The input switch couples an input signal to the summing node when enabled. The output switch couples the summing node to an output signal when enabled. The reset switch shorts the summing node to circuit ground and resets/discharges the capacitors coupled to the summing code when enabled. The input capacitor stores the input signal, shares electrical charge, and provides the output signal in each clock cycle.

In one design, a PSC filter implements a finite impulse response (FIR) filter and includes multiple sections for multiple FIR taps. Each section includes (i) multiple capacitors of equal size determined based on a filter coefficient for an associated FIR tap and (ii) multiple switches that can couple the multiple capacitors to the summing node. The section for FIR tap L, where L=1, 2, . . . , includes L+1 capacitors to store L+1 samples of the input signal for L+1 most recent clock cycles. The L+1 capacitors may be sequentially selected for charging with the input signal, one capacitor in each clock cycle. The capacitor selected for charging in a given clock cycle is selected for charge sharing L clock cycles later, and is then charged in the following clock cycle. In each clock cycle, the input capacitor and one capacitor in each section are charged with the input signal during a first/read phase, and another capacitor in each section is selected for charge sharing during a second phase. The selected capacitor in each section and the input capacitor provide a sample (e.g., a voltage value) for the output signal during a third/write phase, and these capacitors are reset during a fourth/reset phase.

In another design, a PSC filter implements an infinite impulse response (IIR) filter and includes multiple sections for multiple IIR taps. Each section includes (i) at least one capacitor of equal size determined based on a filter coefficient for an associated IIR tap and (ii) at least one switch that can couple the at least one capacitor to the summing node. The section for IIR tap L, where L=1, 2, . . . , includes L capacitors to store L samples of the output signal for L most recent clock cycles. The L capacitors may be sequentially selected for charging with the output signal, one capacitor in each clock cycle. The capacitor selected for charging in a given clock cycle is selected for charge sharing L clock cycles later. In each clock cycle, the input capacitor is charged with the input signal during the first phase, and one capacitor in each section is selected for charge sharing with the input capacitor during the second phase. After the charge sharing is complete, all capacitors involved in the charge sharing have the same sample or voltage value, and each selected capacitor stores its sample. The input capacitor provides its sample to the output signal during the third phase and is reset during the fourth phase.

In yet another design, a PSC filter implements an auto regressive moving average (ARMA) filter composed of a FIR section and an IIR section. The FIR section includes at least one first section for at least one FIR tap. The IIR section includes at least one second section for at least one IIR tap. A first section for FIR tap L includes L+1 capacitors of equal size and used to store L+1 samples of the input signal for L+1 most recent clock cycles. A second section for IIR tap L includes L capacitors of equal size and used to store L samples of the output signal for L most recent clock cycles. In each clock cycle, one capacitor in each first section and one capacitor in each second section are selected for charge sharing to generate a sample for the output signal.

Various aspects and features of the disclosure are described in further detail below.

### BRIEF DESCRIPTION OF THE DRAWINGS

FIG. 1 shows a second-order FIR filter.

FIG. 2 shows a PSC filter that implements the second-order FIR filter.

FIG. 3 shows various control signals for the PSC filter in FIG. 2.

FIG. 4 shows a switching pattern for the PSC filter in FIG. 2.

FIG. 5 shows a process for performing PSC filtering for a FIR filter.

FIG. 6 shows a second-order IIR filter.

FIG. 7 shows a PSC filter that implements the second-order IIR filter.

FIG. 8 shows various control signals for the PSC filter in FIG. 7.

FIG. 9 shows a switching pattern for the PSC filter in FIG. 7.

FIG. 10 shows a process for performing PSC filtering for an IIR filter.

FIG. 11 shows a FIR or IIR filter followed by a decimator.

FIG. 12 shows a PSC filter that implements a FIR filter and a decimator.

FIG. 13 shows a PSC filter that implements an IIR filter and a decimator.

FIG. 14 shows an ARMA filter.

FIG. 15 shows a PSC filter that implements the ARMA filter.

FIG. 16 shows a switching pattern for the PSC filter in FIG. 15.

FIG. 17 shows a lowpass filter composed of two ARMA sections.

FIG. 18 shows frequency response of each filter section in the lowpass filter.

FIG. 19 shows an overall frequency response of the lowpass filter.

FIG. 20 shows a block diagram of a wireless communication device.

### DETAILED DESCRIPTION

The PSC filters described herein may be used for various types of filters such as FIR filters, IIR filters, ARMA filters, etc. The PSC filters may also implement filters of any order, e.g., first, second, third or higher order. Multiple PSC filter sections may be used to form more complex filters. For clarity, PSC filters for a second-order FIR filter and a second-order IIR filter are described in detail below.

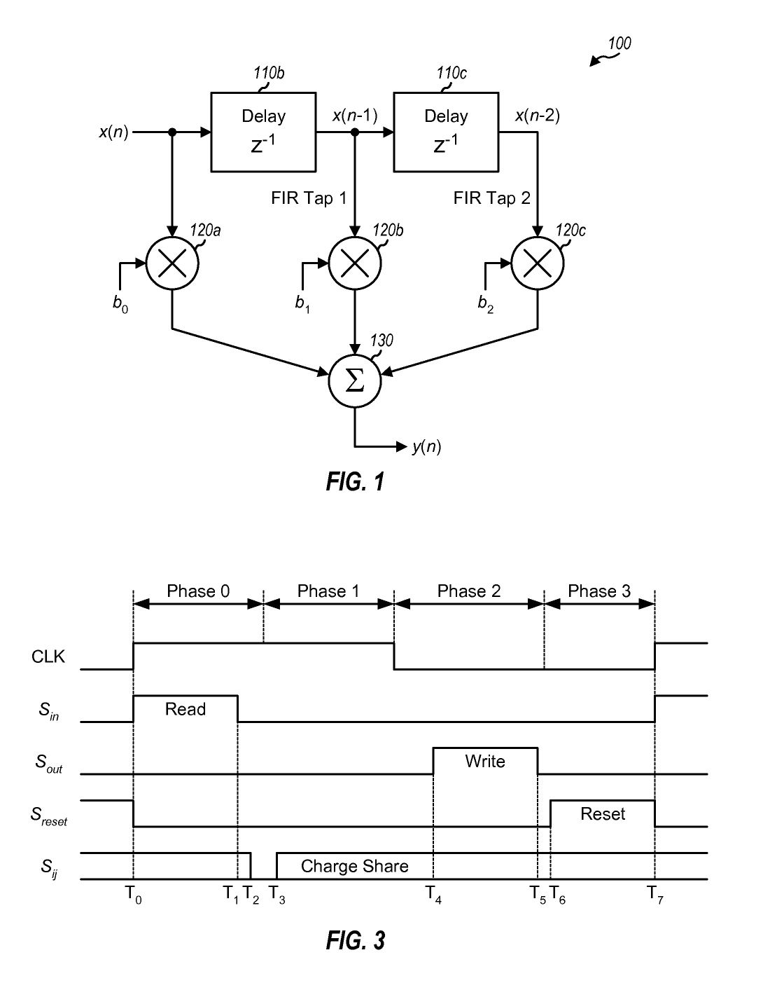

FIG. 1 shows a block diagram of a second-order FIR filter 100 that may be implemented with a PSC filter. FIR filter 100 includes two delay elements 110b and 110c that are coupled in series, with each delay element 110 providing a delay of one clock cycle. Delay element 110b receives an input sample x(n) and provides a delayed sample x(n−1). Delay element 110c receives the delayed sample x(n−1) and provides a delayed sample x(n−2). FIR filter 100 includes two FIR taps 1 and 2 for second order. A multiplier 120a (which may be considered as being for FIR tap 0) is coupled to the input of delay element 110b. A multiplier 120b for FIR tap 1 is coupled to the output of delay element 110b. A multiplier 120c for FIR tap 2 is coupled to the output of delay element 110c. Multipliers 120a, 120b and 120c multiply their samples with filter coefficients b₀, b₁ and b₂, respectively. A summer 130 is coupled to the outputs of all three multipliers 120a, 120b and 120c. Summer 130 sums the outputs of multipliers 120a, 120b and 120c and provides an output sample y(n).

The output sample y(n) from FIR filter 100 may be expressed as:

y(n)=b₀·x(n)+b₁·x(n−1)+b₂·x(n−2). Eq (1)

A transfer function H(z) for FIR filter 100 in the z-domain may be expressed as:

H(z)=b₀+b₁·z+b²·z², Eq (2)

where z^{-k} denotes a delay of k clock cycles.

The filter coefficients may be defined to meet the following condition:

|b₀|+|b₁|+|b₂|=1. Eq (3)

The condition in equation (3) ensures that a PSC filter for FIR filter 100 can meet a power constraint. Any set of FIR filter coefficients may be scaled to achieve the condition in equation (3).

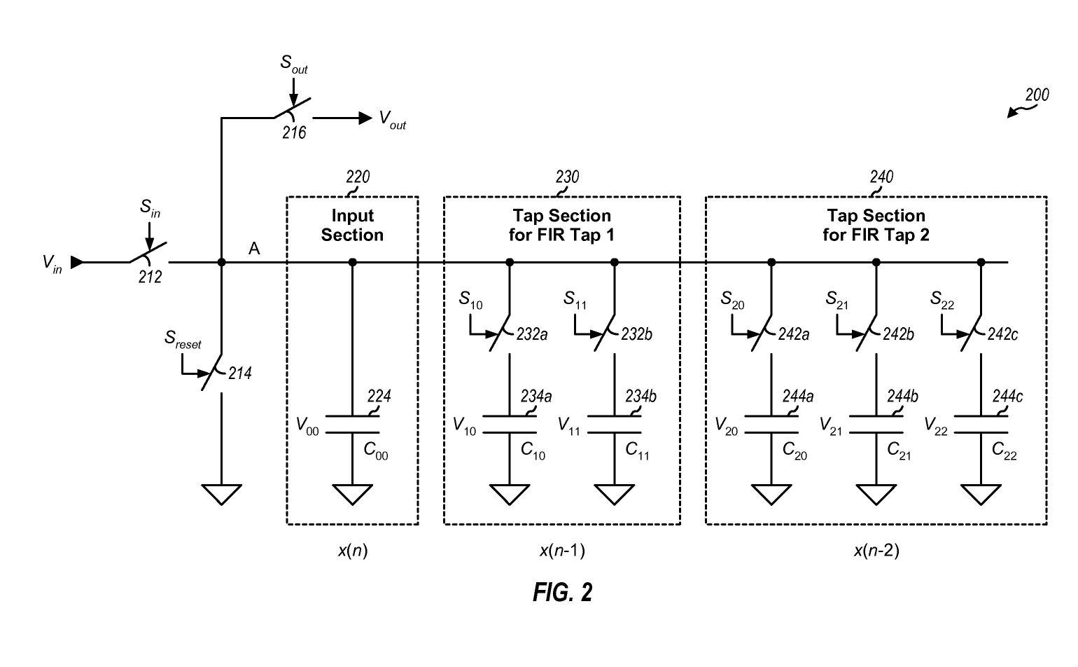

FIG. 2 shows a schematic diagram of a design of a PSC filter 200 that implements second-order FIR filter 100 in FIG. 1. PSC filter 200 includes an input section 220 and two tap sections 230 and 240 for FIR taps 1 and 2, respectively, of FIR filter 100. Within PSC filter 200, an input switch 212 has one end receiving an input signal Vᵢₙ and the other end coupled to a summing node A. A reset switch 214 is coupled between the summing node and circuit ground. An output switch 216 has one end coupled to the summing node and the other end providing an output signal Vₒᵤₜ. Switches 212, 214 and 216 may be implemented with metal oxide semiconductor (MOS) transistors or other types of transistors or switches.

Input section 220 includes an input capacitor 224 coupled between the summing node and circuit ground. Tap section 230 includes two switches 232a and 232b coupled in series with two capacitors 234a and 234b, respectively. Both series combinations of switch 232 and capacitor 234 are coupled between the summing node and circuit ground. Tap section 240 includes three switches 242a, 242b and 242c coupled in series with three capacitors 244a, 244b and 244c, respectively. All three series combinations of switch 242 and capacitor 244 are coupled between the summing node and circuit ground.

All capacitors in each section have the same capacitance/size, which is determined by the corresponding filter coefficient. The capacitances of the capacitors in the three sections of PSC filter 200 may be given as:

C₀₀=K·b₀, Eq (4)

C₁₀=C₁₁=K·b₁, and Eq (5)

C₂₀=C₂₁=C₂₂=K·b₂, Eq (6)

where Cᵢⱼ is the capacitance of the j-th capacitor in the section for FIR tap i, and

K is a scaling constant.

As shown in equations (4) through (6), the size of each capacitor Cᵢⱼ is proportional to the corresponding filter coefficient bᵢ. K may be selected based on various factors such as switching settling time, capacitor size, power dissipation, noise, etc. K may be set to a sufficiently small value so that the settling time can be much larger (e.g. 7 times larger) than the RC constant in order to keep the residue error negligible. Also, capacitor size and power dissipation may be reduced with a small value of K. However, thermal noise and/or fabrication technology may limit the minimum value of K. A negative capacitor for a negative coefficient may be obtained by switching the polarity of the capacitor between a read phase and a charge sharing phase.

In general, the number of capacitors to use for each FIR tap is determined by the delay for that FIR tap. L+1 capacitors of the same size may be used for FIR tap L, where L=1, 2, . . . . Indices L and i are used interchangeably herein. In each clock cycle, one capacitor may be charged with the input signal to store x(n), and another capacitor that was charged L clock cycles earlier and storing x(n−L) may be used to generate y(n) for the output signal. The L+1 capacitors may be charged in a sequential/circular order, one capacitor in each clock cycle, and may store samples x(n) through x(n−L) in any given clock cycle n.

In each clock cycle, switch 212 is closed for a brief period of time to charge one capacitor in each section with the Vᵢₙ signal. The capacitor selected for charging in each tap section is determined by switches 232 and 242, as described below. The total input capacitance observed by the Vᵢₙ signal for the charge operation may be expressed as:

Cᵢₙ=C₀₀+C₁ᵤ+C₂ᵥ, Eq (7)

where u ∈ {0, 1} is an index of the capacitor selected for charging in tap section 230, and

v ∈ {0, 1, 2} is an index of the capacitor selected for charging in tap section 240.

Since the capacitors in each tap section have the same capacitance, the total input capacitance Cᵢₙ is constant for each clock cycle. The constant Cᵢₙ may be desirable for a constant signal insertion loss, which may occur when the signal is provided from a capacitive source to Cᵢₙ. Furthermore, no extra capacitors are needed for Cᵢₙ, which utilizes the capacitors selected for charging in the three sections.

In each clock cycle, an appropriate capacitor in each tap section is used to generate the Vₒᵤₜ signal. For FIR tap L, the capacitor charged L clock cycles earlier and storing x(n−L) is selected for use via its associated switch. The two selected capacitors in tap sections 230 and 240 and input capacitor 224 are used in a charge sharing operation that implements the multiplications with filter coefficients b₀ through b₂ and the summing of the multiplier outputs in equation (1).

The charge sharing operation uses capacitor size to achieve multiplication with a filter coefficient and current summing to achieve summing of the multiplier outputs. For each capacitor within PSC filter 200, the voltage Vᵢⱼ across that capacitor is determined by the Vᵢₙ signal at the time the capacitor is charged, or Vᵢⱼ=Vᵢₙ. The electrical charge Qᵢⱼ stored by each capacitor is determined by the voltage Vᵢⱼ across that capacitor and the capacitance Cᵢⱼ of the capacitor, or Qᵢⱼ=Vᵢⱼ·Cᵢⱼ. In each clock cycle, one capacitor storing the proper sample x(n−L) from each tap section is selected, and the charges from all selected capacitors and input capacitor 224 are shared. The charge sharing for the FIR filter may be expressed as:

$${V}_{out} = \frac{{C}_{00} \cdot {V}_{00} + {C}_{1 p} \cdot {V}_{1 p} + {C}_{2 q} \cdot {V}_{2 q}}{{C}_{00} + {C}_{1 p} + {C}_{2 q}} , \qquad Eq ( 8 )$$

where p ∈ {0, 1} is an index of the capacitor storing x(n−1) in tap section 230, and

q ∈ {0, 1, 2} is an index of the capacitor storing x(n−2) in tap section 240.

Since the capacitors in each tap section have the same capacitance, the total output capacitance Cₒᵤₜ observed by the Vₒᵤₜ signal is constant for each clock cycle and is equal to the total input capacitance, or Cₒᵤₜ=Cᵢₙ. The constant Cₒᵤₜ may be desirable for a constant signal insertion loss, which occurs when the signal is provided from Cₒᵤₜ to a capacitive load. Furthermore, no extra capacitors are needed for Cₒᵤₜ, which utilizes the capacitors used for charge sharing in the three sections.

Index p can cycle between 0 and 1, so that in each clock cycle one capacitor 234 in tap section 230 is charged, and the other capacitor 234 is used for charge sharing. Index q can cycle from 0 through 2, so that in each clock cycle one capacitor 244 in tap section 240 is charged, and another capacitor 244 is used for charge sharing. PSC filter 200 may be considered as having six states for the six different (p, q) combinations.

FIG. 3 shows a timing diagram of various control signals for PSC filter 200 in FIG. 2. A clock signal CLK is shown at the top of the timing diagram. Control signals for the switches within PSC filter 200 are shown below the clock signal. Each clock cycle may be partitioned into four phases 0, 1, 2 and 3.

In the design shown in FIG. 3, each clock cycle includes a read/charge phase (within phase 0), a compute/charge sharing phase (within phase 1), a write/output phase (within phase 2), and a reset/discharge phase (within phase 3). For the read phase from time T₀ to time T₁, the Sᵢₙ control signal is asserted, switch 212 is closed, and input capacitor C₀₀ and one capacitor in each tap section are charged with the Vᵢₙ signal. The Sᵢⱼ control signal for each capacitor selected for charging is asserted during the read phase and de-asserted at time T₂, which may occur after time T₁. For the charge sharing phase starting at time T₃, the Sᵢⱼ control signal for each capacitor selected for charge sharing is asserted, and the selected capacitors and capacitor C₀₀ perform charge sharing via the summing node. For the write phase from time T₄ to time T₅, the Sₒᵤₜ control signal is asserted, switch 216 is closed, and the voltage at the summing node is provided as the Vₒᵤₜ signal. Time T₃ may be sufficiently earlier than time T₄ to ensure that the charge sharing is complete at time T₄. Alternatively, the charge sharing phase and the write phase may overlap, and the Vₒᵤₜ signal may be sampled by a subsequent circuit at a later part of the write phase. For the reset phase from time T₆ to time T₇, the Sᵣₑₛₑₜ control signal is asserted, switch 214 is closed, and the capacitors used for charge sharing are reset/discharged. These capacitors may be charged with the Vᵢₙ signal in the next clock cycle.

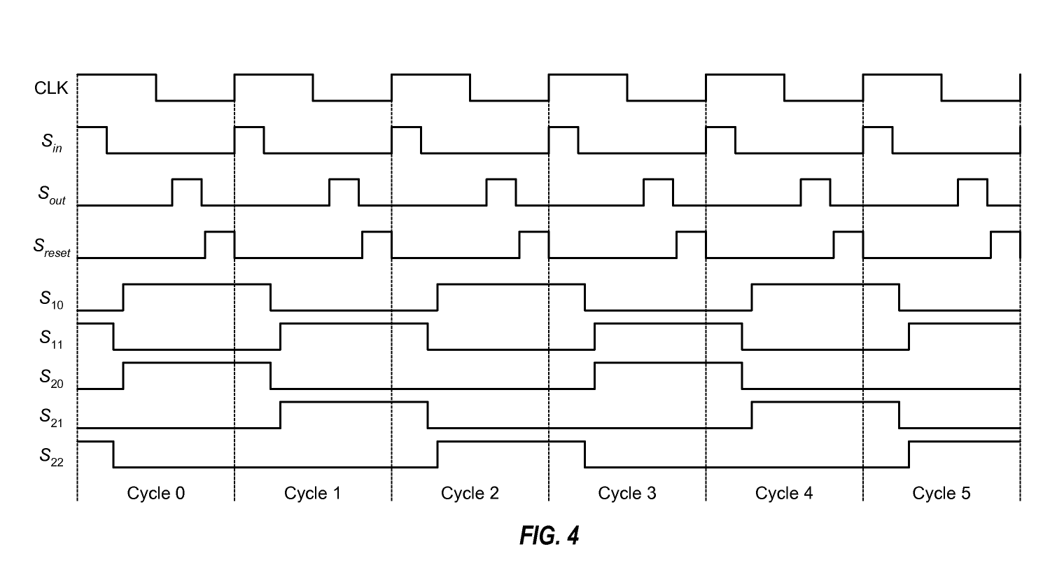

FIG. 4 shows a timing diagram of a switching pattern for PSC filter 200. The switching pattern includes six cycles 0 through 5 for the six different (p, q) combinations and repeats every sixth clock cycles. Table 1 shows the six cycles 0 through 5 and, for each cycle, gives the three capacitors charged with the Vᵢₙ signal and the three capacitors used for charge sharing to generate the Vₒᵤₜ signal.

TABLE 1

| | Capacitors C₀₀, C₁ᵤ and | Capacitors C₀₀, C₁ₚ | | |
|---|---|---|---|---|
| Cycle | C₂ᵥ charged with Vᵢₙ | and C_{2q} used for Vₒᵤₜ | u, v | p, q |
| 0 | C₀₀, C₁₁ and C₂₂ | C₀₀, C₁₀ and C₂₀ | 1, 2 | 0, 0 |
| 1 | C₀₀, C₁₀ and C₂₀ | C₀₀, C₁₁ and C₂₁ | 0, 0 | 1, 1 |
| 2 | C₀₀, C₁₁ and C₂₁ | C₀₀, C₁₀ and C₂₂ | 1, 1 | 0, 2 |
| 3 | C₀₀, C₁₀ and C₂₂ | C₀₀, C₁₁ and C₂₀ | 0, 2 | 1, 0 |
| 4 | C₀₀, C₁₁ and C₂₀ | C₀₀, C₁₀ and C₂₁ | 1, 0 | 0, 1 |
| 5 | C₀₀, C₁₀ and C₂₁ | C₀₀, C₁₁ and C₂₂ | 0, 1 | 1, 2 |

As shown in FIG. 4 and Table 1, for cycle 0, the S₁₁ and S₂₂ control signals are asserted during the read phase, and capacitors C₀₀, C₁₁ and C₂₂ are charged with the Vᵢₙ signal. The S₁₀ and S₂₀ control signals are asserted during the charge sharing phase, and capacitors C₀₀, C₁₀ and C₂₀ are used to generate the Vₒᵤₜ signal. For cycle 1, the S₁₀ and S₂₀ control signals are asserted during the read phase, and capacitors C₀₀, C₁₀ and C₂₀ are charged with the Vᵢₙ signal. These three capacitors were used to generate the Vₒᵤₜ signal in the prior cycle 0. The S₁₁ and S₂₁ control signals are asserted during the charge sharing phase of cycle 1, and capacitors C₀₀, C₁₁ and C₂₁ are used to generate the Vₒᵤₜ signal. Cycles 2 through 5 are described in FIG. 4 and Table 1.

For PSC filter 200, the capacitors in each tap section are selected for charging in a sequential manner, one capacitor in each clock cycle. For input section 220, capacitor C₀₀ is selected for charging in each clock cycle. For tap section 230, index u is cycled from 0 through 1, capacitor C₁₀ is selected for charging in one clock cycle, then capacitor C₁₁ is selected for charging in the next clock cycle, then capacitor C₁₀ is selected for charging in the following clock cycle, etc. For tap section 240, index v is cycled from 0 through 2, capacitor C₂₀ is selected for charging in one clock cycle, then capacitor C₂₁ is selected for charging in the next clock cycle, then capacitor C₂₂ is selected for charging in the following clock cycle, then capacitor C₂₀ is selected for charging in the next clock cycle, etc.

In general, for FIR tap L, the capacitor charged in clock cycle n is selected for charge sharing in clock cycle n+L to achieve a delay of L clock cycles. For input section 220 with L=0, capacitor C₀₀ is used for charge sharing in the same clock cycle that it is charged. For tap section 230 with L=1, the capacitor charged in clock cycle n is selected for charge sharing in clock cycle n+1. For tap section 240 with L=2, the capacitor charged in clock cycle n is selected for charge sharing in clock cycle n+2.

The capacitors used for charge sharing in a given clock cycle are reset at the end of that clock cycle and then charged in the next clock cycle, so that u(n+1)=p(n) and v(n+1)=q(n). There is thus no time gap between the time when a sample is discarded from any given capacitor and the time when that capacitor is reused for a new sample. This results in each capacitor being utilized in each clock cycle, and hence no waste of capacitors.

Table 2 summarizes the action performed by each capacitor in PSC filter 200 in each clock cycle. In Table 2, “store” x(n) means that a capacitor is being charged with a new value from the Vᵢₙ signal in clock cycle n, “hold” x(n) means that the capacitor is holding the stored value in clock cycle n, and x(n)→y(n+L) means that the capacitor is providing the stored value obtained in clock cycle n for charge sharing in clock cycle n+L.

TABLE 2

| | Input | | | | | |
|---|---|---|---|---|---|---|
| | Section | FIR Tap 1 | | FIR Tap 2 | | |
| Clock | Capacitor | Capacitor | Capacitor | Capacitor | Capacitor | Capacitor |
| Cycle | C₀₀ | C₁₀ | C₁₁ | C₂₀ | C₂₁ | C₂₂ |
| n − 1 | don't care | don't care | store x(n − 1) | don't care | hold x(n − 2) | store x(n − 1) |
| n | x(n)→ | store | x(n − 1)→ | store | x(n − 2)→ | hold |
| | y(n) | x(n) | y(n) | x(n) | y(n) | x(n − 1) |
| n + 1 | x(n + 1)→ | x(n)→ | store | hold | store | x(n − 1)→ |
| | y(n + 1) | y(n + 1) | x(n + 1) | x(n) | x(n + 1) | y(n + 1) |
| n + 2 | x(n + 2)→ | store | x(n + 1)→ | x(n)→ | hold | store |
| | y(n + 2) | x(n + 2) | y(n + 2) | y(n + 2) | x(n + 1) | x(n + 2) |
| n + 3 | x(n + 3)→ | x(n + 2)→ | store | store | x(n + 1)→ | hold |
| | y(n + 3) | y(n + 3) | x(n + 3) | x(n + 3) | y(n + 3) | x(n + 2) |
| n + 4 | x(n + 4)→ | store | x(n + 3)→ | hold | store | x(n + 2)→ |
| | y(n + 4) | x(n + 4) | y(n + 4) | x(n + 3) | x(n + 4) | y(n + 4) |
| n + 5 | x(n + 5)→ | x(n + 4)→ | store | x(n + 3)→ | hold | store |
| | y(n + 5) | y(n + 5) | x(n + 5) | y(n + 5) | x(n + 4) | x(n + 5) |
| n + 6 | x(n + 6)→ | store | x(n + 5)→ | store | x(n + 4)→ | hold |
| | y(n + 6) | x(n + 6) | y(n + 6) | x(n + 6) | y(n + 6) | x(n + 5) |
| . | . | . | . | . | . | . |
| . | . | . | . | . | . | . |
| . | . | . | . | . | . | . |

As shown in Table 2, in each clock cycle, one capacitor in each tap section stores the Vᵢₙ signal, and a different capacitor in each tap section provides its stored value for charge sharing to generate the Vₒᵤₜ signal. Capacitor C₀₀ stores the Vᵢₙ signal during the read phase of each clock cycle and provides the stored value during the charge sharing phase of the same clock cycle. For FIR tap 1, a delay of one clock cycle is obtained by charging a capacitor in clock cycle n and using that capacitor for charge sharing in clock cycle n+1. For FIR tap 2, a delay of two clock cycles is obtained by charging a capacitor in clock cycle n and using that capacitor for charge sharing in clock cycle n+2. In each clock cycle n, a stored value x(n) from capacitor C₀₀ in input section 220, a stored value x(n−1) from one capacitor in tap section 230, and a stored value x(n−2) from one capacitor in tap section 240 are used to obtain the Vₒᵤₜ signal.

Referring back to FIG. 2, input capacitor 224 may be coupled directly between the summing node A and circuit ground. A switch may also be coupled in series with capacitor 224 for matching and/or other reasons.

FIG. 2 shows a design of PSC filter 200 for second-order FIR filter 100 in FIG. 1. In general, a PSC filter may implement a FIR filter of any order N. For an N-th order FIR filter, the PSC filter may include N tap sections and an input section. The tap section for FIR tap L, where L ∈ {1, . . . , N}, may include L+1 capacitors of the same size determined based on filter coefficient b_{L} for FIR tap L. The L+1 capacitors in the tap section for FIR tap L may be selected for charging in a sequential order, one capacitor in each clock cycle. The capacitor that is charged in clock cycle n may be used for charge sharing in clock cycle n+L. This capacitor may be reset at the end of clock cycle n+L and then charged with a new value in the next clock cycle n+L+1.

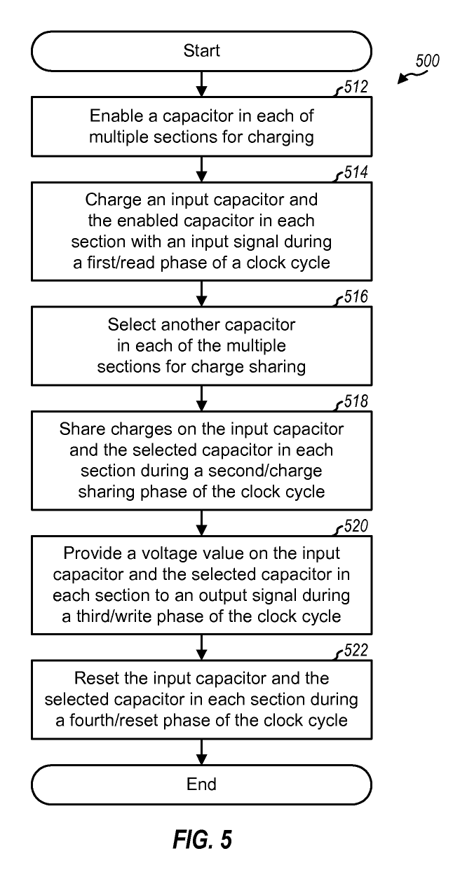

FIG. 5 shows a design of a process 500 for performing PSC filtering for a FIR filter. Process 500 may be performed in each clock cycle. A capacitor in each of multiple sections may be enabled for charging (block 512). Each section may include multiple capacitors, and the capacitors in each section may be enabled for charging by cycling through these capacitors and selecting a different capacitor in each clock cycle.

An input capacitor and the enabled capacitor in each section may be charged with an input signal during a first/read phase of the clock cycle (block 514). Another capacitor in each of the multiple sections may be selected for charge sharing (block 516). Charges on the input capacitor and the selected capacitor in each section may be shared during a second/charge sharing phase of the clock cycle (block 518). A voltage value on the input capacitor and the selected capacitor in each section may be provided as an output signal during a third/write phase of the clock cycle (block 520). The input capacitor and the selected capacitor in each section may be reset/discharged during a fourth/reset phase of the clock cycle (block 522).

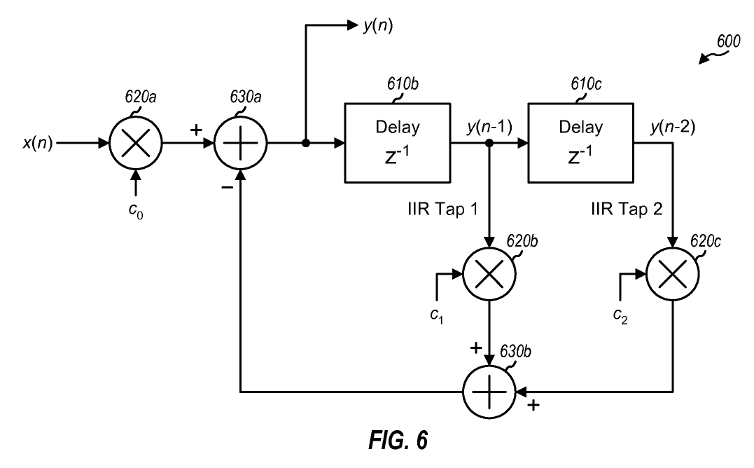

FIG. 6 shows a block diagram of a second-order IIR filter 600 that may be implemented with a PSC filter. Within IIR filter 600, a multiplier 620a receives and scales an input sample x(n) with a filter coefficient c₀. A summer 630a subtracts the output of a summer 630b from the output of multiplier 620a and provides an output sample y(n).

Two delay elements 610b and 610c are coupled in series, with each delay element 610 providing a delay of one clock cycle. Delay element 610b receives the output sample y(n) and provides a delayed sample y(n−1). Delay element 610c receives delayed sample y(n−1) and provides a delayed sample y(n−2). IIR filter 600 includes two IIR taps 1 and 2 for second order. A multiplier 620b for IIR tap 1 is coupled to the output of delay element 610b. A multiplier 620c for IIR tap 2 is coupled to the output of delay element 610c. Multipliers 620b and 620c multiply their samples with filter coefficients c₁ and c₂, respectively, for the two IIR taps. Summer 630b sums the outputs of multipliers 620b and 620c and provides its output to summer 630a.

The output sample y(n) from IIR filter 600 may be expressed as:

y(n)=c₀·x(n)−c₁·y(n−1)−c₂·y(n−2). Eq (9)

A transfer function H(z) for IIR filter 600 may be expressed as:

$$H ( z ) = \frac{{c}_{0}}{1 + {c}_{1} \cdot {z}^{- 1} + {c}_{2} \cdot {z}^{- 2}} . \qquad Eq ( 10 )$$

The filter coefficients may be defined to meet the following condition:

|c₀|+|c₁|+|c₂|=1. Eq (11)

The condition in equation (11) ensures that a PSC filter for IIR filter 600 can meet a power constraint. Filter coefficients c₁ and c₂ may be selected to obtain a desired frequency response for IIR filter 600. If |c₁+|c₂|<1, then c₀ may be defined as c₀=1−|c₁|−|c₂|. If |c₁|+|c₂|>1, then other techniques may be used to implement the IIR filter.

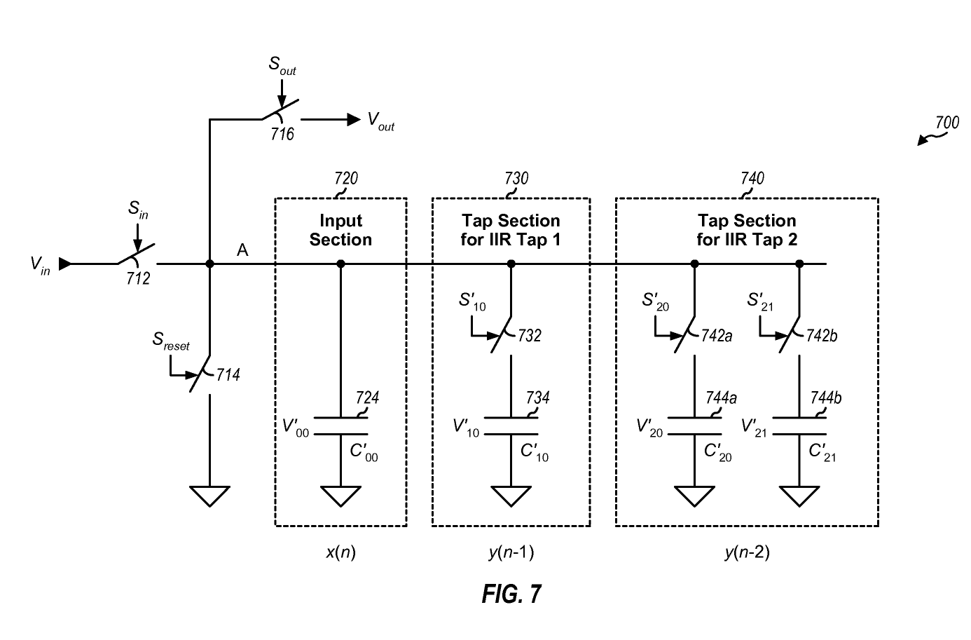

FIG. 7 shows a schematic diagram of a design of a PSC filter 700 that implements second-order IIR filter 600 in FIG. 6. PSC filter 700 includes an input section 720 and two tap sections 730 and 740 for IIR taps 1 and 2, respectively, of IIR filter 600. Within PSC filter 700, an input switch 712 has one end receiving an input signal Vᵢₙ and the other end coupled to a summing node A. A reset switch 714 is coupled between the summing node and circuit ground. An output switch 716 has one end coupled to the summing node and the other end providing an output signal Vₒᵤₜ.

Input section 720 includes a capacitor 724 coupled between the summing node and circuit ground. Tap section 730 includes a switch 732 coupled in series with a capacitor 734, the combination of which is coupled between the summing node and circuit ground. Tap section 740 includes two switches 742a and 742b coupled in series with two capacitors 744a and 744b, respectively. Both series combinations of switch 742 and capacitor 744 are coupled between the summing node and circuit ground. Capacitor 734 in tap section 730 and capacitors 744a and 744b in tap section 740 may be reset at the start of filtering operation.

All capacitors in each section of PSC filter 700 have the same capacitance, which is determined by the filter coefficients. The capacitances of the capacitors in the three sections of PSC filter 700 may be given as:

C₀₀′=K·c₀, Eq (12)

C₁₀′=K c₁, and Eq (13)

C₂₀′=C₂₁′=K·c₂. Eq (14)

As shown in equations (12) through (14), the size of each capacitor Cᵢⱼ′ is proportional to the magnitude of the corresponding filter coefficient cᵢ. A negative capacitor for a negative coefficient may be obtained by switching the polarity of the capacitor between the read phase and the charge sharing phase.

In general, the number of capacitors to use for each IIR tap is determined by the delay for that IIR tap. L capacitors of the same size may be used for IIR tap L, where L=1, 2, . . . . In each clock cycle, one capacitor that was charged L clock cycles earlier and storing y(n−L) may be used to generate y(n) for the output signal, and this capacitor may store y(n) for use to generate y(n+L). The L capacitors may be charged in a sequential order, one capacitor in each clock cycle, and may store samples y(n) through y(n−L+1) in any given clock cycle n.

In each clock cycle, switch 712 is closed for a brief period of time to charge capacitor 724 in section 720 with the Vᵢₙ signal. The total input capacitance observed by the Vᵢₙ signal is thus Cᵢₙ=C₀₀′, and no extra capacitors are needed for Cᵢₙ.

In each clock cycle, an appropriate capacitor in each tap section is used to generate the Vₒᵤₜ signal. For IIR tap L, the capacitor charged L clock cycles earlier and storing y(n−L) is selected for charge sharing via its associated switch. Two selected capacitors in tap sections 730 and 740 and input capacitor 724 are used in a charge sharing operation that implements the multiplications with filter coefficients c₀ through c₂ and the summing of the multiplier outputs in equation (9). The charge sharing for the IIR filter may be expressed as:

$${V}_{out} = \frac{{C}_{00}^{′} \cdot {V}_{00}^{′} + {C}_{10}^{′} \cdot {V}_{10}^{′} + {C}_{2 m}^{′} \cdot {V}_{2 m}^{′}}{{C}_{00}^{′} + {C}_{10}^{′} + {C}_{2 m}^{′}} , \qquad Eq ( 15 )$$

where m ∈ {0, 1} is an index of the capacitor storing y(n−2) in tap section 740.

After completing the charge sharing, the voltage across capacitors C₀₀′, C₁₀′ and C₂ₘ′ corresponds to y(n). Capacitors C₁₀′ and C₂ₘ′ may store y(n) for use in subsequent clock cycles. Capacitor C₀₀′ may provide y(n) for the Vₒᵤₜ signal. The total output capacitance observed by the Vₒᵤₜ signal is Cₒᵤₜ=C₀₀′, and no extra capacitors are needed for Cₒᵤₜ.

Index m can cycle between 0 and 1, so that each capacitor 744 in tap section 740 is used for charge sharing in alternate clock cycle. PSC filter 700 may be considered as having two states for the two possible values of m.

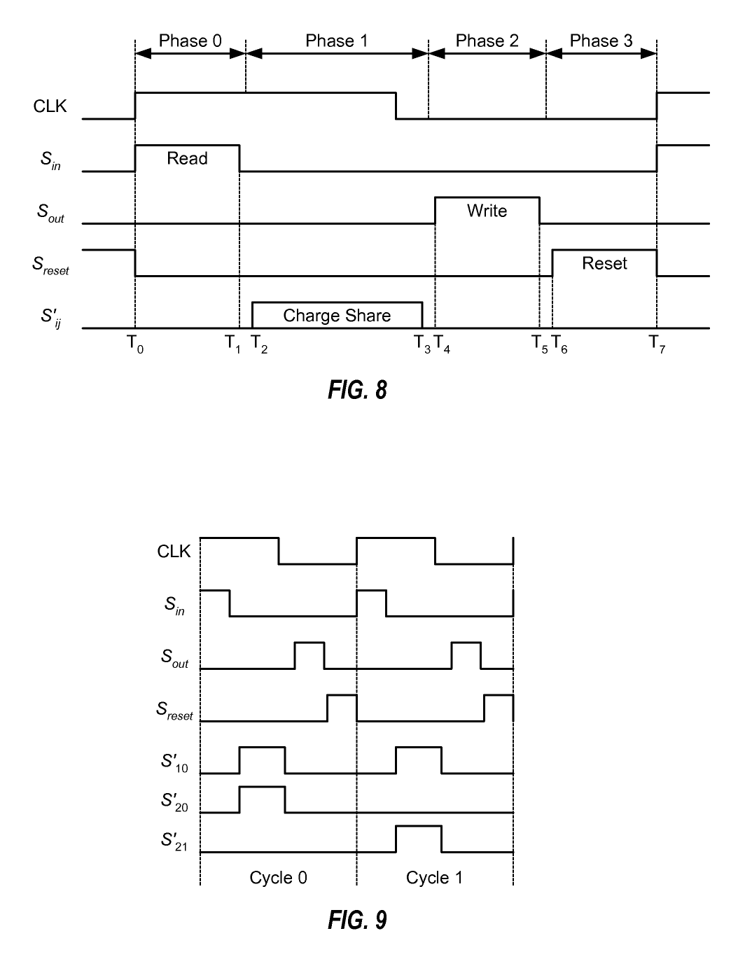

FIG. 8 shows a timing diagram of various control signals for PSC filter 700 in FIG. 7. The clock signal CLK is shown at the top of the timing diagram. Control signals for the switches within PSC filter 700 are shown below the clock signal. Each clock cycle may be partitioned into four phases 0, 1, 2 and 3.

In the design shown in FIG. 8, each clock cycle includes a read phase (within phase 0), a charge sharing phase (within phase 1), a write phase (within phase 2), and a reset phase (within phase 3). For the read phase from time T₀ to time T₁, the Sᵢₙ control signal is asserted, switch 712 is closed, and input capacitor C₀₀′ is charged with the Vᵢₙ signal. For the charge sharing phase from time T₂ to time T₃, the Sᵢₙ control signal for each capacitor selected for charge sharing is asserted, and the selected capacitors and input capacitor C₀₀′ perform charge sharing via the summing node. At the end of the charge sharing phase, the Sᵢⱼ′ control signal for each selected capacitor is de-asserted at time T₃, which then causes that capacitor to store y(n). For the write phase from time T₄ to time T₅, the Sₒᵤₜ control signal is asserted, switch 716 is closed, and capacitor C₀₀′ provides y(n) to the Vₒᵤₜ signal. For the reset phase from time T₆ to time T₇, the Sᵣₑₛₑₜ control signal is asserted, switch 714 is closed, and capacitor C₀₀′ is reset.

FIG. 9 shows a timing diagram of a switching pattern for PSC filter 700. The switching pattern includes two cycles 0 and 1 for the two possible values of m and repeats every two clock cycles. Table 3 shows the two cycles 0 and 1 and, for each cycle, gives the three capacitors used to generate the Vₒᵤₜ signal.

TABLE 3

| | Capacitors C₀₀′, C₁₀′ and | |
|---|---|---|
| Cycle | C₂ₘ′ used for Vₒᵤₜ | m |
| 0 | C₀₀′, C₁₀′ and C₂₀′ | 0 |
| 1 | C₀₀′, C₁₀′ and C₂₁′ | 1 |

For cycle 0, only input capacitor C₀₀′ is charged with the Vᵢₙ signal. The S₁₀′ and S₂₀′ control signals are asserted during the charge sharing phase, and capacitors C₀₀′, C₁₀′ and C₂₀′ are used to generate the Vₒᵤₜ signal. Capacitors C₁₀′ and C₂₀′ store the Vₒᵤₜ signal at the end of the charge sharing phase. For cycle 1, only capacitor C₀₀′ is charged with the Vᵢₙ signal. The S₁₀′ and S₂₁′ control signals are asserted during the charge sharing phase, and capacitors C₀₀′, C₁₀′ and C₂₁′ are used to generate the Vₒᵤₜ signal. Capacitors C₁₀′ and C₂₁′ store the Vₒᵤₜ signal at the end of the charge sharing phase.

For PSC filter 700, capacitor C₀₀′ in section 720 is charged with the Vᵢₙ signal in each clock cycle and is also used for charge sharing in the same clock cycle. For tap section 730, capacitor C₁₀′ is used for charge sharing in each clock cycle and stores y(n) for use in the next clock cycle. For tap section 740, index m toggles between 0 and 1, capacitor C₂₀′ is selected for charge sharing in one clock cycle, then capacitor C₂₁′ is selected for charge sharing in the following clock cycle, etc.

In general, for IIR tap L, the capacitor used for charge sharing in clock cycle n stores y(n) after completing the charge sharing. This capacitor is selected for charge sharing again in clock cycle n+L to achieve a delay of L clock cycles. For tap section 730 with L=1, capacitor C₁₀′ is used for charge sharing in clock cycle n, stores y(n) after completing the charge sharing, and is used for charge sharing again in clock cycle n+1 to provide y(n) in the computation of y(n+1). For tap section 740 with L=2, one capacitor is used for charge sharing in clock cycle n, stores y(n) after completing the charge sharing, and is used for charge sharing again in clock cycle n+2 to provide y(n) in the computation of y(n+2). For each tap section, the capacitors used for charge sharing in a given clock cycle is used to store y(n) after completing the charge sharing. There is thus no time gap between the time when a sample is discarded from any given capacitor and the time when that capacitor is reused for a new sample. This results in each capacitor being utilized in each clock cycle, and hence no waste of capacitors.

Table 4 summarizes the action performed by each capacitor in PSC filter 700 in each clock cycle.

TABLE 4

| Clock | Input Section | IIR Tap 1 | IIR Tap 2 | |
|---|---|---|---|---|
| Cycle | Capacitor C₀₀′ | Capacitor C₁₀′ | Capacitor C₂₀′ | Capacitor C₂₁′ |
| n | store x(n) | y(n − 1)→y(n) | y(n − 2)→y(n) | hold y(n − 1) |
| | x(n)→y(n) | store y(n) | store y(n) | |
| n + 1 | store x(n + 1) | y(n)→y(n + 1) | hold y(n) | y(n − 1)→y(n + 1) |
| | x(n + 1)→y(n + 1) | store y(n + 1) | | store y(n + 1) |
| n + 2 | store x(n + 2) | y(n + 1)→y(n + 2) | y(n)→y(n + 2) | hold y(n + 1) |
| | x(n + 2)→y(n + 2) | store y(n + 2) | store y(n + 2) | |
| . | . | . | . | . |
| . | . | . | . | . |
| . | . | . | . | . |

As shown in Table 4, in each clock cycle, only input capacitor C₀₀′ stores the Vᵢₙ signal. In each clock cycle, one capacitor in each section provides the stored value for charge sharing to generate the Vₒᵤₜ signal. For IIR tap 1, a delay of one clock cycle is obtained by storing y(n) in capacitor C₁₀′ in clock cycle n and using this capacitor for charge sharing in clock cycle n+1. For IIR tap 2, a delay of two clock cycles is obtained by storing y(n) in a capacitor in clock cycle n and using that capacitor for charge sharing in clock cycle n+2. In each clock cycle n, a stored value x(n) from capacitor C₀₀′, a stored value y(n−1) from capacitor C₁₀′ in tap section 730, and a stored value y(n−2) from one capacitor in tap section 740 are used to obtain the Vₒᵤₜ signal.

Referring back to FIG. 7, input capacitor 724 may be coupled directly between the summing node A and circuit ground. A switch may also be coupled in series with capacitor 724 for matching and/or other reasons.

FIG. 7 shows a design of PSC filter 700 for second-order IIR filter 600 in FIG. 6. In general, a PSC filter may implement an IIR filter of any order N. For an N-th order IIR filter, the PSC filter may include N tap sections and an input section. The capacitors in all N tap sections may be reset at the start of filtering operation. The tap section for IIR tap L, where L ∈ {1, . . . , N}, may include L capacitors of the same size determined based on filter coefficient c_{L} for IIR tap L. The L capacitors in the tap section may be selected for charge sharing in a sequential order, one capacitor in each clock cycle. The capacitor that is used for charge sharing in clock cycle n may store y(n) after completion of the charge sharing and may be used for charge sharing again in clock cycle n+L.

FIG. 10 shows a design of a process 1000 for performing PSC filtering for an IIR filter. Process 1000 may be performed in each clock cycle. An input capacitor may be charged with an input signal during a first/read phase of the clock cycle (block 1012). A capacitor in each of multiple sections may be selected for charge sharing (block 1014). Each section may include at least one capacitor, and the capacitor(s) in each section may be selected for charge sharing by cycling through the capacitor(s) and selecting a different capacitor in each clock cycle.

Charges on the input capacitor and the selected capacitor in each section may be shared during a second/charge sharing phase of the clock cycle to obtain a voltage value (block 1016). The voltage value on the selected capacitor in each section may be stored at end of the second phase (block 1018). The voltage value on the input capacitor may be provided as an output signal during a third/write phase of the clock cycle (block 1020). The input capacitor may be reset/discharged during a fourth/reset phase of the clock cycle (block 1022).

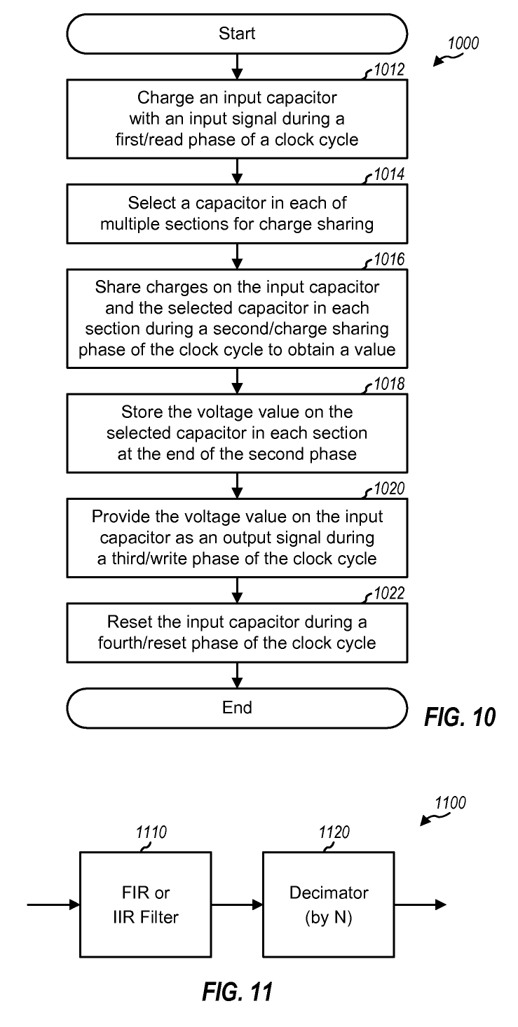

FIG. 11 shows a design of a PSC filter 1100 composed of a FIR or IIR filter 1110 followed by a decimator 1120. Decimator 1120 may receive input samples at an input sample rate of fᵢₙ from FIR or IIR filter 1110 and may provide output samples at an output sample rate of fₒᵤₜ=fᵢₙ/N, where N>1 is a decimation factor. Decimator 1120 may be a non-summing decimator and may provide one input sample out of every N input samples and may discard the other N−1 input samples. The non-summing decimator may be merged with FIR or IIR filter 1110 and may be implemented by simply enabling switch 216 within FIR filter 200 in FIG. 2 or switch 716 within IIR filter 700 in FIG. 7 once every N clock cycles for decimation by N (instead of once every clock cycle for no decimation). However, the non-summing decimator would waste energy by not using the N−1 discarded samples in every N input samples.

Decimator 1120 may also be a summing decimator and may sum N input samples and provide one output sample. The summing decimator is equivalent to an N-tap FIR filter followed by a non-summing decimator. The summing decimator can provide lowpass filtering, with the filter response being dependent on the N weights for the N input samples being summed for each output sample. In general, any set of weights may be applied to the N input samples being summed. However, a non-weighted sum with equal weights for all N input samples may be adequate for most applications and may result in simpler implementation of the summing decimator. In any case, the lowpass filtering provided by the summing decimator may simplify filtering requirement of preceding FIR or IIR filter 1110.

As an example, it may be desirable to implement an 8-tap FIR filter with tap coefficients of [1 3 5 7 7 5 3 1] followed by a non-summing decimator with a decimation factor of 4. This combination of FIR filter and non-summing decimator may be implemented with a 5-tap FIR filter with tap coefficients of [1 2 2 2 1] followed by a summing decimator with a decimation factor of 4 and equal weights of [1 1 1 1]. The summing decimator may thus reduce the complexity and size of the preceding FIR filter. For example, the 8-tap FIR filter and non-summing decimator may be implemented with 144 unit capacitors whereas the 5-tap FIR filter and summing decimator may be implemented with 48 unit capacitors.

To simplify implementation, decimator 1120 may be merged with preceding FIR or IIR filter 1110. The merged design may reduce insertion loss over a separate design in which FIR or IIR filter 1110 and decimator 1120 are implemented with separate PSC stages. In particular, the separate design would have (i) insertion loss between the preceding FIR/IIR filter 1110 and decimator 1120 and (ii) insertion loss between decimator 1120 and a succeeding stage (not shown in FIG. 11).

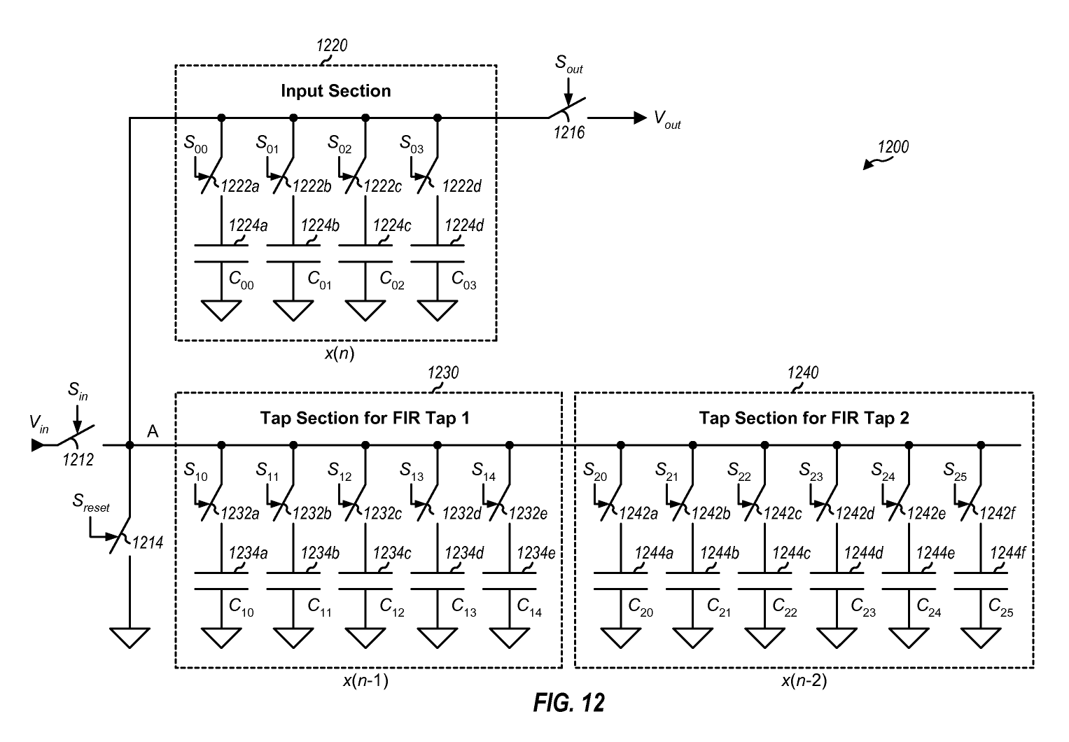

FIG. 12 shows a schematic diagram of a design of a PSC filter 1200 that implements a second-order FIR filter and a summing decimator with a decimation factor of N=4. PSC filter 1200 includes an input section 1220 and two tap sections 1230 and 1240 for FIR taps 1 and 2, respectively. Within PSC filter 1200, an input switch 1212, a reset switch 1214, and an output switch 1216 are coupled in the same manner as switches 212, 214 and 216, respectively, in PSC filter 200 in FIG. 2.

Input section 1220 includes four switches 1222a to 1222d coupled in series with four capacitors 1224a to 1224d, respectively. The four series combinations of switch 1222 and capacitor 1224 are coupled between a summing node A and circuit ground. Tap section 1230 includes five switches 1232a to 1232e coupled in series with five capacitors 1234a to 1234e, respectively. The five series combinations of switch 1232 and capacitor 1234 are coupled between the summing node and circuit ground. Tap section 1240 includes six switches 1242a to 1242f coupled in series with six capacitors 1244a to 1244f, respectively. The six series combinations of switch 1242 and capacitor 1244 are coupled between the summing node and circuit ground. All capacitors in each section may have the same capacitance/size, which may be determined by the corresponding filter coefficient as described above.

In general, for decimation by N, input section 1220 may include N capacitors 1224, tap section 1230 may include N+1 capacitors 1234, and tap section 1240 may include N+2 capacitors 1244. Each section with decimation by N may thus include N−1 more capacitors than the corresponding section without decimation. Output switch 1216 may be enabled once every N clock cycles for decimation by N (instead of once every clock cycle without decimation). In every N-th clock cycle, N samples within each tap section (instead of one sample per tap section without decimation) may be selected and combined to obtain an output sample.

Each clock cycle may be partitioned into four phases 0, 1, 2 and 3, as shown in FIG. 3. During phase 0 of each clock cycle, input switch 1212 is closed, and one capacitor 1224 in input section 1220, one capacitor 1234 in tap section 1230, and one capacitor 1244 in tap section 1240 are charged by the Vᵢₙ signal. During phase 1 of each clock cycle, another capacitor 1224 in input section 1220, another capacitor 1234 in tap section 1230, and another capacitor 1244 in tap section 1240 are selected for summing, share their charges, and store the resultant value. During phase 2 of every fourth clock cycle, four capacitors 1224 in input section 1220, four capacitors 1234 in tap section 1230, and four capacitors 1244 in tap section 1240 are selected for summing, share their charges, and provide the resultant value via output switch 1216 to the Vₒᵤₜ signal. During phase 3 of each clock cycle, reset switch 1214 is closed, and the capacitors selected during phase 2 are reset/discharged. Table 5 summarizes the capacitors selected for each of phases 0, 1, 2 and 3 in each clock cycle.

TABLE 5

| Clock | Phase 0 | Phase 1 | Phase 2 | Phase 3 |
|---|---|---|---|---|
| Cycle | Charge | Sum and Store | Sum and Output | Reset/Discharge |
| 0 | C₀₀, C₁₁, C₂₂ | C₀₀, C₁₀, C₂₀ | — | — |
| 1 | C₀₁, C₁₂, C₂₃ | C₀₁, C₁₁, C₂₁ | — | — |
| 2 | C₀₂, C₁₃, C₂₄ | C₀₂, C₁₂, C₂₂ | — | — |
| 3 | C₀₃, C₁₄, C₂₅ | C₀₃, C₁₃, C₂₃ | C₀₀, C₀₁, C₀₂, C₀₃ | C₀₀, C₀₁, C₀₂, C₀₃ |
| | | | C₁₀, C₁₁, C₁₂, C₁₃ | C₁₀, C₁₁, C₁₂, C₁₃ |
| | | | C₂₀, C₂₁, C₂₂, C₂₃ | C₂₀, C₂₁, C₂₂, C₂₃ |
| 4 | C₀₀, C₁₀, C₂₀ | C₀₀, C₁₄, C₂₄ | — | — |
| 5 | C₀₁, C₁₁, C₂₁ | C₀₁, C₁₀, C₂₅ | — | — |
| 6 | C₀₂, C₁₂, C₂₂ | C₀₂, C₁₁, C₂₀ | — | — |
| 7 | C₀₃, C₁₃, C₂₃ | C₀₃, C₁₂, C₂₁ | C₀₀, C₀₁, C₀₂, C₀₃ | C₀₀, C₀₁, C₀₂, C₀₃ |
| | | | C₁₄, C₁₀, C₁₁, C₁₂ | C₁₄, C₁₀, C₁₁, C₁₂ |
| | | | C₂₄, C₂₅, C₂₀, C₂₁ | C₂₄, C₂₅, C₂₀, C₂₁ |
| 8 | C₀₀, C₁₄, C₂₄ | C₀₀, C₁₃, C₂₂ | — | — |
| 9 | C₀₁, C₁₀, C₂₅ | C₀₁, C₁₄, C₂₃ | — | — |
| 10 | C₀₂, C₁₁, C₂₀ | C₀₂, C₁₀, C₂₄ | — | — |
| 11 | C₀₃, C₁₂, C₂₁ | C₀₃, C₁₁, C₂₅ | C₀₀, C₀₁, C₀₂, C₀₃ | C₀₀, C₀₁, C₀₂, C₀₃ |
| | | | C₁₃, C₁₄, C₁₀, C₁₁ | C₁₃, C₁₄, C₁₀, C₁₁ |
| | | | C₂₂, C₂₃, C₂₄, C₂₅ | C₂₂, C₂₃, C₂₄, C₂₅ |
| 12 | C₀₀, C₁₃, C₂₂ | C₀₀, C₁₂, C₂₀ | — | — |
| . | . | . | . | . |
| . | . | . | . | . |
| . | . | . | . | . |

The design in FIG. 12 allows capacitors in both the input section and the tap sections to be used to provide the Vₒᵤₜ signal during the write phase. In another design of a PSC filter for a FIR filter and a merged decimator, the input section may include a single capacitor. This design may be used, e.g., in case the input capacitor size is small relative to the capacitor sizes of the other tap sections. The single input capacitor may reduce size and may have acceptable insertion loss (due to a smaller total output capacitance).

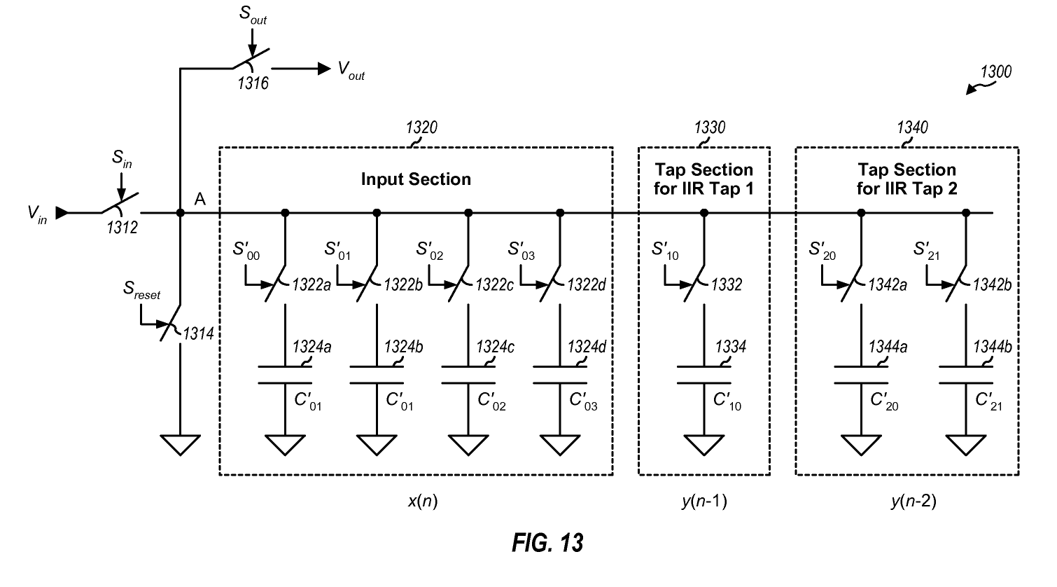

FIG. 13 shows a schematic diagram of a design of a PSC filter 1300 that implements a second-order IIR filter and a summing decimator with a decimation factor of N=4. PSC filter 1300 includes an input section 1320 and two tap sections 1330 and 1340 for IIR taps 1 and 2, respectively. Within PSC filter 1300, an input switch 1312, a reset switch 1314, and an output switch 1316 are coupled in the same manner as switches 712, 714 and 716, respectively, in PSC filter 700 in FIG. 7.

Input section 1320 includes four switches 1322a to 1322d coupled to four capacitor 1324a to 1324d, respectively. The four series combinations of switch 1322 and capacitor 1324 are coupled between a summing node A and circuit ground. Tap section 1330 includes a switch 1332 coupled in series with a capacitor 1334, the combination of which is coupled between the summing node and circuit ground. Tap section 1340 includes two switches 1342a and 1342b coupled in series with two capacitors 1344a and 1344b, respectively. Both series combinations of switch 1342 and capacitor 1344 are coupled between the summing node and circuit ground. Capacitor 1334 in tap section 1330 and capacitors 1344a and 1344b in tap section 1340 may be reset at the start of filtering operation. All capacitors in each section of PSC filter 1300 may have the same capacitance, which may be determined by the filter coefficients as described above.

In general, for decimation by N, input section 1320 may include N capacitors 1324. Each tap section with decimation by N may include the same number of capacitors as the corresponding tap section without decimation. Output switch 1316 may be enabled once every N clock cycles for decimation by N (instead of once every clock cycle without decimation). In every N-th clock cycle, N samples from input section 1320 may be combined to obtain an output sample.

Each clock cycle may be partitioned into four phases 0, 1, 2 and 3, as shown in FIG. 8. During phase 0 of each clock cycle, input switch 1212 is closed, and one capacitor 1324 in input section 1320 is charged by the Vᵢₙ signal. During phase 1 of each clock cycle, one capacitor 1324 in input section 1320, capacitor 1334 in tap section 1330, and one capacitor 1344 in tap section 1340 are selected for summing, share their charges, and store the resultant value. During phase 2 of every fourth clock cycle, all four capacitors 1324 in input section 1330 are selected for summing, share their charges, and provide the resultant value via output switch 1316 to the Vₒᵤₜ signal. During phase 3 of every fourth clock cycle in which an output sample is provided to the Vₒᵤₜ signal, reset switch 1314 is closed, and the four capacitors 1324 in input section 1320 are reset/discharged. Table 6 summarizes the capacitors selected for each of phases 0, 1, 2 and 3 in each clock cycle.

TABLE 6

| Clock | Phase 0 | Phase 1 | Phase 2 | Phase 3 |
|---|---|---|---|---|
| Cycle | Charge | Sum and Store | Sum and Output | Reset/Discharge |
| 0 | — | — | — | C₁₀, C₂₀, C₂₁ |
| 1 | C₀₀ | C₀₀, C₁₀, C₂₀ | — | — |
| 2 | C₀₁ | C₀₁, C₁₀, C₂₁ | — | — |
| 3 | C₀₂ | C₀₂, C₁₀, C₂₀ | — | — |
| 4 | C₀₃ | C₀₃, C₁₀, C₂₁ | C₀₀, C₀₁, C₀₂, C₀₃ | C₀₀, C₀₁, C₀₂, C₀₃ |
| 5 | C₀₀ | C₀₀, C₁₀, C₂₀ | — | — |
| 6 | C₀₁ | C₀₁, C₁₀, C₂₁ | — | — |
| 7 | C₀₂ | C₀₂, C₁₀, C₂₀ | — | — |
| 8 | C₀₃ | C₀₃, C₁₀, C₂₁ | C₀₀, C₀₁, C₀₂, C₀₃ | C₀₀, C₀₁, C₀₂, C₀₃ |
| 9 | C₀₀ | C₀₀, C₁₀, C₂₀ | — | — |
| . | . | . | . | . |
| . | . | . | . | . |
| . | . | . | . | . |

FIGS. 12 and 13 show two designs of PSC filters having a decimator merged with a preceding FIR filter and a preceding IIR filter, respectively. A decimator may also be merged with a succeeding FIR filter or a succeeding IIR filter.

A FIR section and an IIR section may be combined into an ARMA filter, which may have certain advantages. For example, the ARMA filter may be able to synthesize a more complex filter response and may have lower insertion loss.

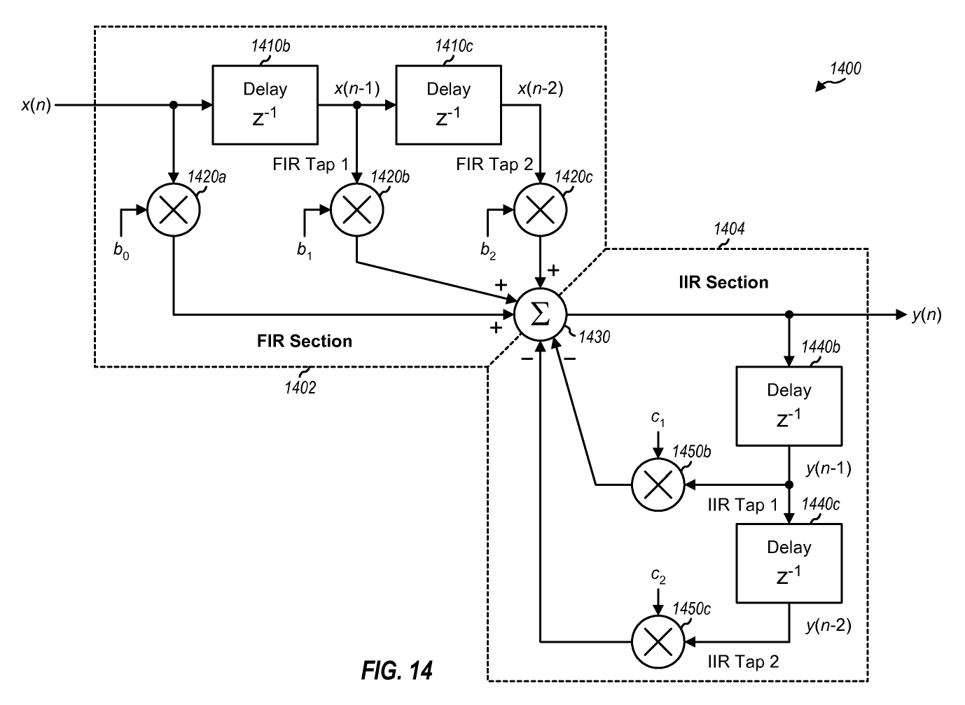

FIG. 14 shows a block diagram of an ARMA filter 1400 that may be implemented with a PSC filter. ARMA filter 1400 includes a second-order FIR section 1402 and a second-order IIR section 1404. FIR section 1402 includes two delay elements 1410b and 1410c, three multipliers 1420a, 1420b and 1420c, and a summer 1430 that are coupled as described above for delay elements 110b and 110c, multipliers 120a, 120b and 120c, and summer 130 within FIR filter 100 in FIG. 1. IIR section 1404 includes two delay elements 1440b and 1440c, two multipliers 1450b and 1450c, and summer 1430 that are coupled as described above for delay elements 610b and 610c, multipliers 620b and 620c, and summers 630a and 630b within IIR filter 600 in FIG. 6. Summer 1430 is shared by both FIR section 1402 and IIR section 1404.

The output sample y(n) from ARMA filter 1400 may be expressed as:

y(n)=b₀·x(n)+b₁·x(n−1)+b₂·x(n−2)−c₁·y(n−1)−c₂·y(n−2) Eq (16)

A transfer function H(z) for ARMA filter 1400 may be expressed as:

$$H ( z ) = \frac{{b}_{0} + {b}_{1} \cdot {z}^{- 1} + {b}_{2} \cdot {z}^{- 2}}{1 + {c}_{1} \cdot {z}^{- 1} + {c}_{2} \cdot {z}^{- 2}} . \qquad Eq ( 17 )$$

The filter coefficients may be defined to meet the following condition:

|b₀|+|b₁|+|b₂|+|c₁|+|c₂|=1. Eq (18)

The condition in equation (18) ensures that a PSC filter for ARMA filter 1400 can meet a power constraint. Filter coefficients b₀, b₁ and b₂ may be selected to obtain a desired frequency response for FIR section 1402. Filter coefficients c₁ and c₂ may be selected to obtain a desired frequency response for IIR section 1404.

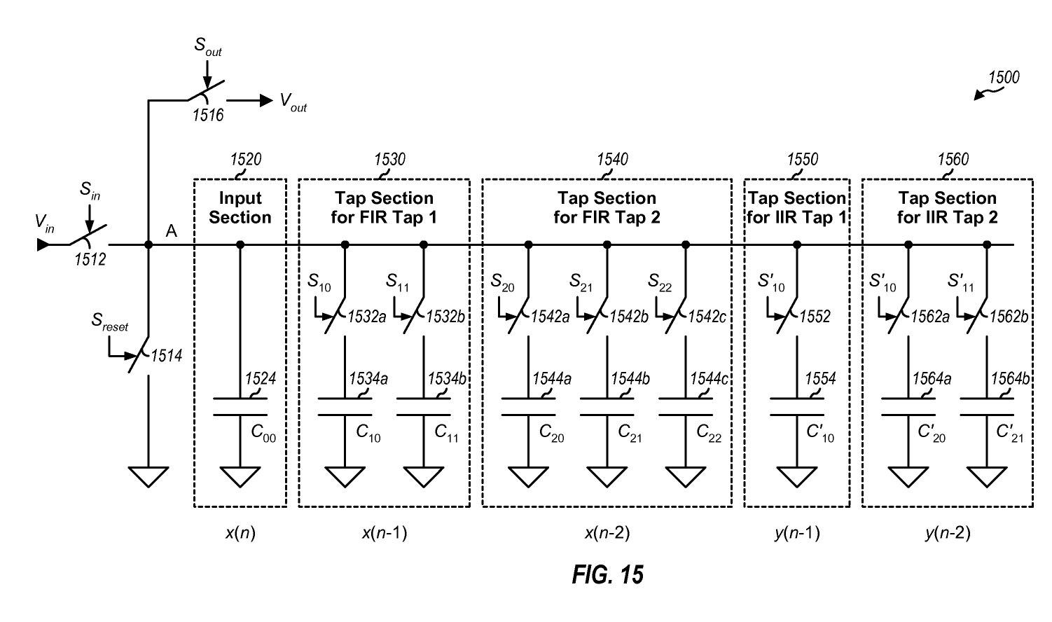

FIG. 15 shows a schematic diagram of a design of a PSC filter 1500 that implements ARMA filter 1400 in FIG. 14. PSC filter 1500 includes an input section 1520, tap sections 1530 and 1540 for FIR taps 1 and 2, respectively, of FIR section 1402, and tap sections 1550 and 1560 for IIR taps 1 and 2, respectively, of IIR section 1404. Within PSC filter 1500, an input switch 1512 has one end receiving an input signal Vᵢₙ and the other end coupled to a summing node A. A reset switch 1514 is coupled between the summing node and circuit ground. An output switch 1516 has one end coupled to the summing node and the other end providing an output signal Vₒᵤₜ.

Input section 1520 includes a capacitor 1524 coupled between the summing node and circuit ground. Tap section 1530 includes two switches 1532a and 1532b coupled in series with two capacitors 1534a and 1534b, respectively, between the summing node and circuit ground. Tap section 1540 includes three switches 1542a, 1542b and 1542c coupled in series with three capacitors 1544a, 1544b and 1544c, respectively, between the summing node and circuit ground. Tap section 1550 includes a switch 1552 and a capacitor 1554 coupled in series and between the summing node and circuit ground. Tap section 1560 includes two switches 1562a and 1562b coupled in series with two capacitors 1564a and 1564b, respectively, between the summing node and circuit ground.

All capacitors in each tap section have the same capacitance, which is determined by the filter coefficient for the corresponding FIR or IIR tap. The capacitances of the capacitors in sections 1520, 1530 and 1540 may be given as shown in equations (4), (5) and (6), respectively. The capacitances of the capacitors in tap sections 1550 and 1560 may be given as shown in equations (13) and (14), respectively.

The sizes of the capacitors in the FIR and IIR sections of the ARMA filter may be selected to meet the power constraint. If (|c₁|+|c₂|)<1, then |b₀|+|b₁|+|b₂| may be scaled down to be equal to 1−(|c₁|+|c₂|). If (|c₁|+|c₂|)≧1, then other techniques may be applied to resolve the power constraint, similar to the IIR case.

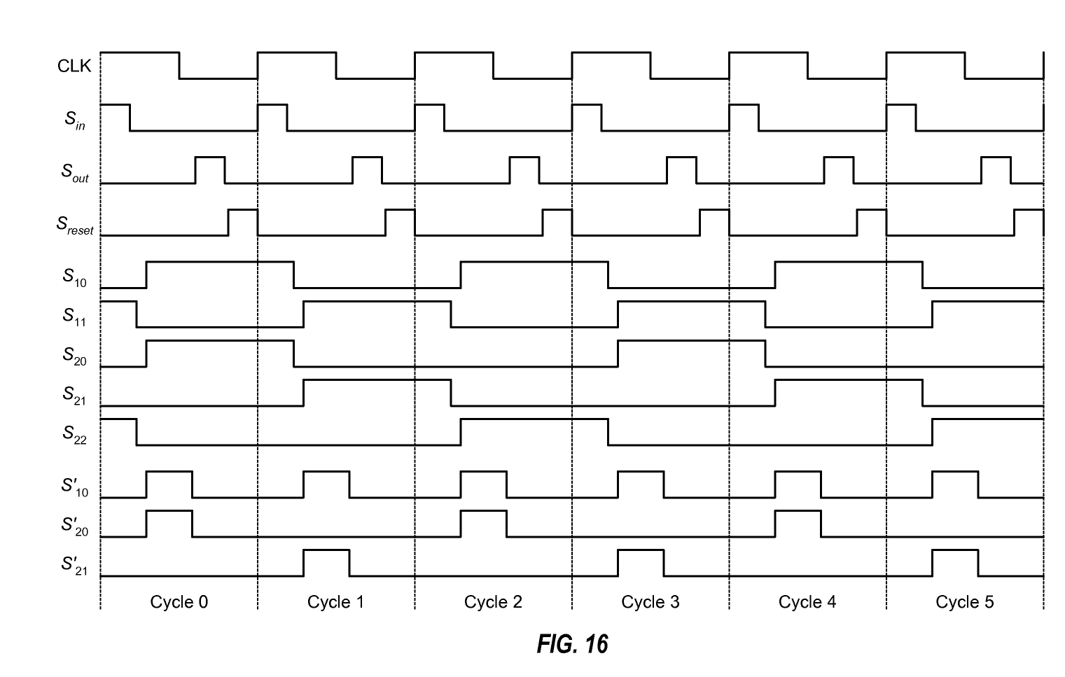

FIG. 16 shows a timing diagram of a switching pattern for PSC filter 1500. The switching pattern includes six cycles 0 through 5 for the six different (p, q) combinations for FIR section 1402 and repeats every sixth clock cycles. The two cycles 0 and 1 for the two possible values of m for IIR section 1404 are repeated three times within the six cycles 0 through 5 for FIR section 1402.

The Sᵢₙ, Sₒᵤₜ, Sᵣₑₛₑₜ and Sᵢⱼ control signals for FIR section 1402 for the six cycles 0 through 5 are as shown in FIG. 4. The Sᵢⱼ′ control signals for IIR section 1404 for the two cycles 0 and 1 are as shown in FIG. 9. Each clock cycle includes a read phase, a charge sharing phase, a write phase, and a reset phase. For the read phase, the Sᵢₙ control signal is asserted, switch 1512 is closed, and one capacitor in each of sections 1520, 1530 and 1540 is charged with the Vᵢₙ signal. For the charge sharing phase, the Sᵢⱼ and Sᵢⱼ′ control signals for all capacitors selected for charge sharing are asserted, and the selected capacitors and input capacitor C₀₀ perform charge sharing via the summing node. After the charge sharing is complete, the Sᵢⱼ′ control signals for all capacitors used for charge sharing in tap sections 1550 and 160 are de-asserted. For the write phase, the Sₒᵤₜ control signal is asserted, switch 1516 is closed, and the voltage value from the selected capacitors in sections 1530 and 1540 and capacitor C₀₀ is provided to the Vₒᵤₜ signal. For the reset phase, the Sᵣₑₛₑₜ control signal is asserted, switch 1514 is closed, and the selected capacitors in sections 1530 and 1540 and capacitor C₀₀ are reset/discharged.

A more complex filter may be implemented by cascading multiple FIR sections, multiple IIR sections, multiple ARMA sections, or any combination thereof. In general, each filter section may have any order and any filter response.

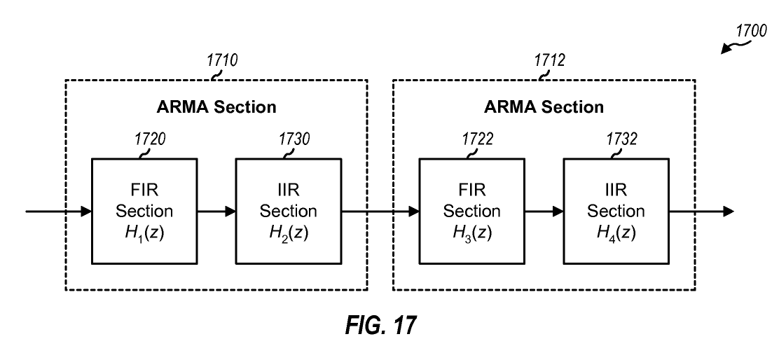

FIG. 17 shows a block diagram of a design of a filter 1700 composed of two ARMA sections 1710 and 1712. ARMA section 1710 includes a FIR section 1720 having a transfer function of H₁(z) and an IIR section 1730 having a transfer function of H₂(z). ARMA section 1712 includes a FIR section 1722 having a transfer function of H₃(z) and an IIR section 1732 having a transfer function of H₄(z).

In one design, filter 1700 is a lowpass filter having a bandwidth of 0.25·fₛₐₘₚ, where fₛₐₘₚ is the sampling rate or clock rate. Filter 1700 also provides 20 dB of attenuation from 0.2645·fₛₐₘₚ to 0.5·fₛₐₘₚ. The overall transfer function H(z) of filter 1700 may be expressed as:

$$\begin{matrix}H ( z ) = g \cdot {H}_{1} ( z ) \cdot {H}_{2} ( z ) \cdot {H}_{3} ( z ) \cdot {H}_{4} ( z ) \\ = 0.25 \cdot \frac{( 1 + 1.25 {z}^{- 1} + {z}^{- 2} ) \cdot ( 1 + 0.25 {z}^{- 1} + {z}^{- 2} )}{( 1 - 0.375 {z}^{- 1} + 0.375 {z}^{- 2} ) \cdot ( 1 + 0.875 {z}^{- 2} )} ,\end{matrix} \qquad Eq ( 19 )$$

where H₁(z)=1+1.25z⁻¹+z⁻², Eq (20)

H₂(z)=1/(1−0.375z¹+0.375z⁻²), Eq (21)

H₃(z)=1+0.25z⁻¹+z⁻², and Eq (22)

H₄(z)=1/(1+0.875z⁻²). Eq (23)

As shown in equation (19), the overall transfer function H(z) is composed of two second-order FIR sections with transfer functions H₁(z) and H₃(z) and two second-order IIR sections with transfer functions H₂(z) and H₄(z).

The capacitors for FIR section 1720 with H₁(z) may be computed as shown in equations (4) to (6) and given as:

C₀₀;C₁₀:C₁₁;C₂₀:C₂₁:C₂₂=1;1.25:1.25;1:1:1=4;5:5;4:4:4. Eq (24)

The capacitors for FIR section 1722 with H₃(z) may be given as:

C₀₀;C₁₀:C₁₁;C₂₀:C₂₁:C₂₂=1;0.25:0.25;1:1:1=4;1:1;4:4:4. Eq (25)

The capacitors for IIR section 1730 with H₂(z) may be given as:

C₀₀;C₁₀;C₂₀:C₂₁=0.25;0.375;0.375:0.375=2;3;3:3. Eq (26)

The capacitors for IIR section 1732 with H₄(z) may be given as:

C₀₀;C₁₀;C₂₀:C₂₁=0.125;0;0.875:0.875=1;0;7:7. Eq (27)

Capacitor C₀₀ for each IIR section is selected based on the power constraint shown in equation (11).

Equations (24) through (27) give the capacitor sizes for the four filter sections if each filter section is implemented separately, e.g., as shown in FIG. 2 or 7. As noted above, a negative capacitor for a negative filter coefficient may be implemented by switching the polarity of the capacitor. If a FIR section and an IIR section are implemented as an ARMA section, e.g., as shown in FIG. 15, then the capacitors for the FIR and IIR sections may be scaled to meet the power constraint. If multiple filter sections are coupled in cascade, then insertion loss between the filter sections may be reduced by starting with the filter section having the largest capacitors and then going to filter sections with progressively smaller capacitors.

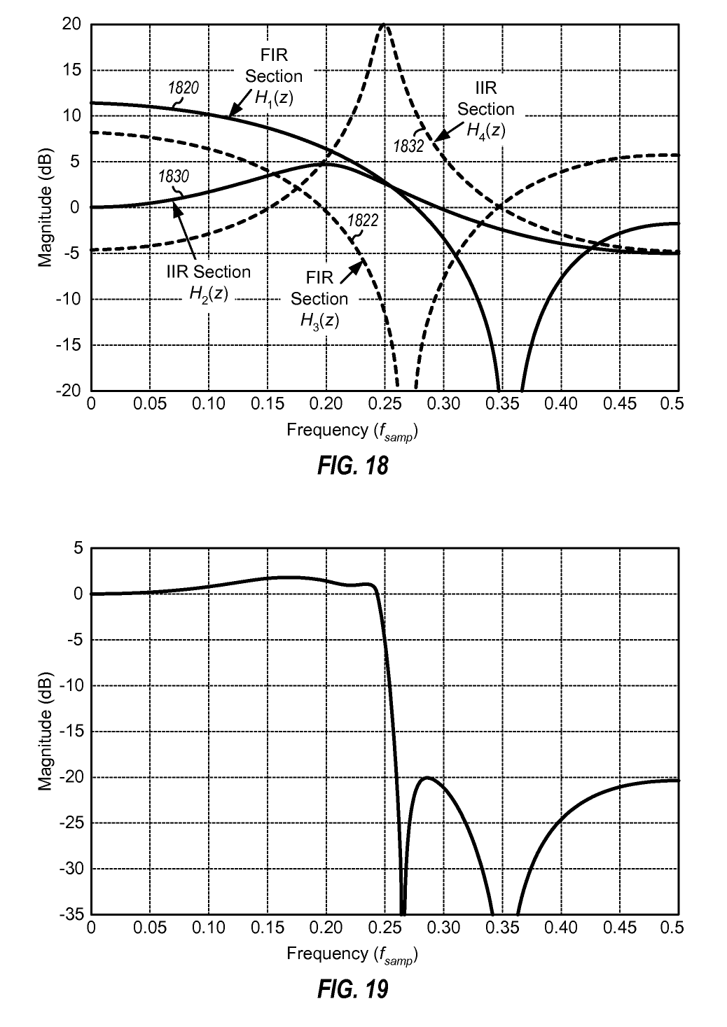

FIG. 18 shows the frequency response of each filter section within filter 1700. A plot 1820 shows the frequency response of FIR section 1720 with H₁(z) shown in equation (20). A plot 1830 shows the frequency response of IIR section 1730 with H₂(z) shown in equation (21). A plot 1822 shows the frequency response of FIR section 1722 with H₃(z) shown in equation (22). A plot 1832 shows the frequency response of IIR section 1732 with H₄(z) shown in equation (23). The FIR sections have only zeros and can pass or attenuate a signal. The IIR sections have poles and can provide gain at certain frequencies.

FIG. 19 shows the overall frequency response of filter 1700. Filter 1700 has a passband from DC to 0.25·fₛₐₘₚ and a stopband from 0.2645·fₛₐₘₚ to 0.5·fₛₐₘₚ. Filter 1700 has less than 3 dB ripple in the passband and at least 20 dB of attenuation in the stopband.

FIG. 17 shows an example design of a filter composed of four sections. In general, a filter may include any number of sections, and each section may be of any type (e.g., FIR or IIR) and any order (e.g., second or possibly higher order). Each filter section may be implemented with a PSC section, e.g., as shown in FIG. 2 or 7. The multiple filter sections may be operated such that the write phase for one filter section coincides with the read phase for the next filter section, e.g., the Sₒᵤₜ control signal for one section is used as the Sᵢₙ control signal for the next section.

The PSC filters described herein may provide certain advantages. First, the PSC filters do not utilize an amplifier within the filter, which may reduce size and power consumption. Amplifiers may be used for input/output buffering. Second, the PSC filters may be able to provide an accurate frequency response, which is determined by capacitance ratios that can be more accurately achieved in an integrated circuit (IC). Third, the PSC filters may have high adaptability since it uses an array of capacitors that may be configured during operation, e.g., to obtain different filter responses.

The PSC filters described herein may be used for various applications such as wireless communication, computing, networking, consumer electronics, etc. The PSC filters may also be used for various devices such as wireless communication devices, cellular phones, broadcast receivers, personal digital assistants (PDAs), handheld devices, wireless modems, laptop computers, cordless phones, Bluetooth devices, consumer electronics devices, etc. For clarity, the use of the PSC filters in a wireless communication device, which may be a cellular phone or some other device, is described below. The PSC filters may be used to pass a desired signal, to attenuate jammers and out-of-band noise and interference, and/or to perform other functions in the wireless device.

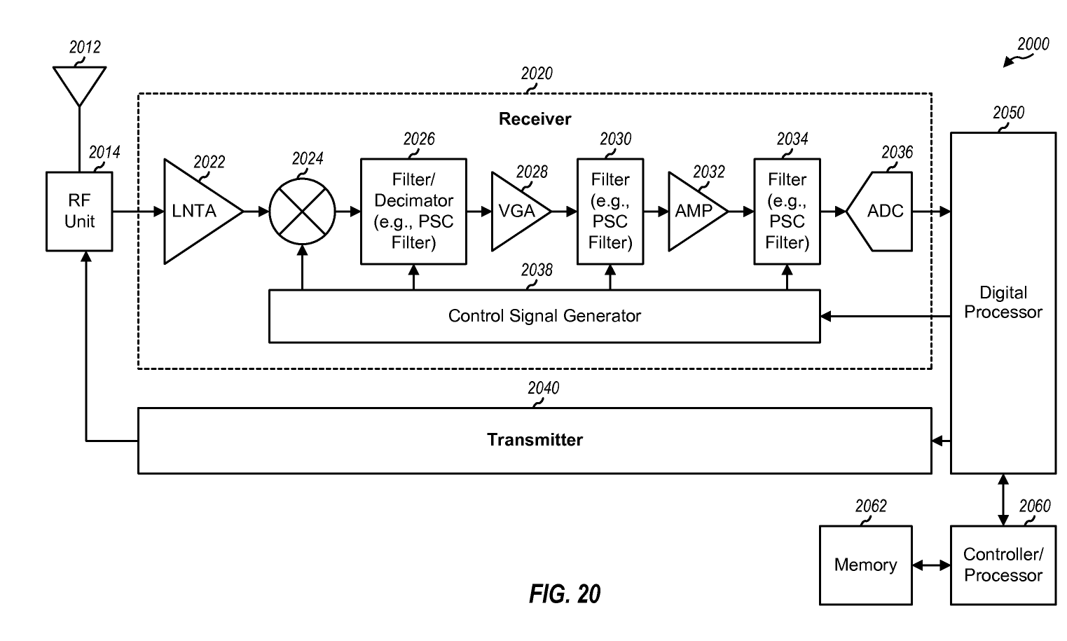

FIG. 20 shows a block diagram of a design of a wireless communication device 2000 in which the PSC filters described herein may be implemented. Wireless device 2000 includes a receiver 2020 and a transmitter 2040 that support bi-directional communication. In general, wireless device 2000 may include any number of receivers and any number of transmitters for any number of communication systems and frequency bands.

On the receive path, an antenna 2012 may receive radio frequency (RF) modulated signals transmitted by base stations and provide a received RF signal, which may be routed through an RF unit 2014 and provided to receiver 2020. RF unit 2014 may include an RF switch and/or a duplexer that can multiplex RF signals for the transmit and receive paths. Within receiver 2020, a low noise transconductance amplifier (LNTA) 2022 may amplify the received RF signal (which may be a voltage signal) and provide an amplified RF signal (which may be a current signal). A passive sampler 2024 may sample the amplified RF signal, perform frequency downconversion via a sampling operation, and provide analog samples. An analog sample is an analog value for a discrete time instant. A filter/decimator 2026 may filter the analog samples, perform decimation, and provide filtered samples at a lower sample rate. Filter/ decimator 2026 may be implemented with any of the PSC filters described herein.

The filtered samples from filter/decimator 2026 may be amplified by a variable gain amplifier (VGA) 2028, filtered by a filter 2030, further amplified by an amplifier (AMP) 2032, further filtered by a filter 2034, and digitized by an analog-to-digital converter (ADC) 2036 to obtain digital samples. Filter 2030 and/or 2034 may be implemented with any of the PSC filters described herein. VGA 2028 and/or amplifier 2032 may be implemented with switched-capacitor amplifiers that can amplify the analog samples from filters 2026 and 2030. A digital processor 2050 may process the digital samples to obtain decoded data and signaling. A control signal generator 2038 may generate a sampling clock for passive sampler 2024 and control signals for filters 2026, 2030 and 2034. The control signals may be as shown in FIG. 3, 4, 8, 9 or 16.

On the transmit path, transmitter 2040 may process output samples from digital processor 2050 and provide an output RF signal, which may be routed through RF unit 2014 and transmitted via antenna 2012. For simplicity, details of transmitter 2040 are not shown in FIG. 20.

Digital processor 2050 may include various processing units for data transmission and reception as well as other functions. For example, digital processor 2050 may include a digital signal processor (DSP), a reduced instruction set computer (RISC) processor, a central processing unit (CPU), etc. A controller/processor 2060 may control the operation at wireless device 2000. A memory 2062 may store program codes and data for wireless device 2000. Data processor 2050, controller/processor 2060, and/or memory 2062 may be implemented on one or more application specific integrated circuits (ASICS) and/or other ICs.

FIG. 20 shows a specific design of receiver 2020. In general, the conditioning of the signals within receiver 2020 may be performed by one or more stages of mixer, amplifier, filter, etc. These circuit blocks may be arranged differently from the configuration shown in FIG. 20. Furthermore, other circuit blocks not shown in FIG. 20 may also be used to condition the signals in the receiver. Some circuit blocks in FIG. 20 may also be omitted. All or a portion of receiver 2020 may be implemented on one or more RF ICs (RFICs), mixed-signal ICs, etc.

The received RF signal from antenna 2012 may contain both a desired signal and jammers. A jammer is a large amplitude undesired signal that is close in frequency to a desired signal. The jammers may be attenuated prior to ADC 2036 to avoid saturation of the ADC. Filters 2026, 2030 and/or 2034 may attenuate the jammers and other out-of-band noise and interference and may each be implemented with any of the PSC filters described herein.

The PSC filters described herein may be implemented on an IC, an analog IC, an RFIC, a mixed-signal IC, an ASIC, a printed circuit board (PCB), an electronics device, etc. The PSC filters may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), etc.

An apparatus implementing any of the PSC filters described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the scope of the disclosure. Thus, the disclosure is not intended to be limited to the examples and designs described herein but is to be accorded the widest scope consistent with the principles and novel features disclosed herein.

What is claimed is:

1. An apparatus comprising:
a passive switched-capacitor (PSC) filter operative to receive an input signal and provide an output signal, the PSC filter comprising
a plurality of capacitors operative to store and share electrical charge, and
a plurality of switches operative to couple the plurality of capacitors to a summing node, each switch coupling an associated capacitor to the summing node when enabled and decoupling the associated capacitor from the summing node when disabled, each capacitor storing a value from the summing node when selected for charging and sharing electrical charge with other capacitors via the summing node when selected for charge sharing.

2. The apparatus of claim 1, the PSC filter further comprising
an input capacitor coupled between the summing node and circuit ground and operative to store the input signal, share electrical charge, and provide the output signal in each clock cycle.

3. The apparatus of claim 1, the PSC filter further comprising
an input switch operative to couple the input signal to the summing node when the switch is enabled.

4. The apparatus of claim 1, the PSC filter further comprising
an output switch operative to couple the summing node to the output signal when the switch is enabled.

5. The apparatus of claim 1, the PSC filter further comprising
a reset switch operative to couple the summing node to circuit ground and to reset capacitors coupled to the summing code when the switch is enabled.

6. The apparatus of claim 1, the PSC filter implementing a finite impulse response (FIR) filter.

7. The apparatus of claim 1, the PSC filter implementing an infinite impulse response (IIR) filter.

8. The apparatus of claim 1, the PSC filter implementing a finite impulse response (FIR) or an infinite impulse response (IIR) filter and further implementing a summing decimator, the PSC filter receiving the input signal at an input sample rate and providing the output signal at an output sample rate, the input sample rate being multiple times the output sample rate.

9. The apparatus of claim 1, further comprising:
a control signal generator operative to generate control signals for the plurality of switches.

10. An apparatus comprising:
multiple sections for multiple filter taps, each section comprising
at least one capacitor of equal size determined based on a coefficient for an associated filter tap, and
at least one switch operative to couple the at least one capacitor to a summing node, each switch coupling an associated capacitor to the summing node when enabled and decoupling the associated capacitor from the summing node when disabled, each capacitor storing a value from the summing node when selected for charging and sharing electrical charge with one or more other capacitors via the summing node when selected for charge sharing.

11. The apparatus of claim 10, further comprising:
an input capacitor coupled between the summing node and circuit ground and operative to store the input signal, share electrical charge, and provide the output signal in each clock cycle.

12. The apparatus of claim 10, wherein the multiple sections are for multiple filter taps of a finite impulse response (FIR) filter, and wherein a section for filter tap L includes L+1 capacitors of equal size determined based on a coefficient for filter tap L, where L is one or greater.

13. The apparatus of claim 12, wherein the L+1 capacitors in the section for filter tap L store L+1 samples of an input signal for L+1 most recent clock cycles.

14. The apparatus of claim 12, wherein the L+1 capacitors in the section for filter tap L are sequentially selected for charging with an input signal, one capacitor in each clock cycle.

15. The apparatus of claim 12, wherein for each section a capacitor selected for charging in a clock cycle is selected for charge sharing L clock cycles later.

16. The apparatus of claim 12, wherein the L+1 capacitors in the section for filter tap L are sequentially selected for charge sharing, one capacitor in each clock cycle.

17. The apparatus of claim 16, wherein for each section a capacitor selected for charge sharing in a clock cycle is selected for charging in next clock cycle.

18. The apparatus of claim 12, wherein in each clock cycle one capacitor in each section is charged with an input signal during a first phase of the clock cycle and another capacitor in each section is selected for charge sharing during a second phase of the clock cycle.

19. The apparatus of claim 18, wherein in each clock cycle the capacitor in each section selected for charge sharing provides a value to an output signal during a third phase of the clock cycle and is reset during a fourth phase of the clock cycle.

20. The apparatus of claim 19, wherein the first, second, third and fourth phases occur in sequential order in each clock cycle.

21. The apparatus of claim 10, wherein the multiple sections are for multiple filter taps of an infinite impulse response (IIR) filter, and wherein a section for filter tap L includes L capacitors of equal size determined based on a coefficient for filter tap L, where L is one or greater.

22. The apparatus of claim 21, wherein the L capacitors in the section for filter tap L store L samples of an output signal for L most recent clock cycles.

23. The apparatus of claim 21, wherein the L capacitors in the section for filter tap L are sequentially selected for charging with an output signal, one capacitor in each clock cycle.

24. The apparatus of claim 21, wherein for each section a capacitor selected for charging in a clock cycle is selected for charge sharing L clock cycles later.

25. The apparatus of claim 21, wherein the L capacitors in the section for filter tap L are sequentially selected for charge sharing, one capacitor in each clock cycle.

26. The apparatus of claim 21, wherein for each section a capacitor selected for charge sharing in a clock cycle later stores a value for an output signal in the same clock cycle.

27. The apparatus of claim 21, further comprising:
an input capacitor coupled between the summing node and circuit ground and operative to be charged with an input signal during a first phase of each clock cycle, wherein one capacitor in each section and the input capacitor are selected for charge sharing during a second phase of each clock cycle.

28. The apparatus of claim 27, wherein in each clock cycle the input capacitor provides the output signal during a third phase of the clock cycle and is reset during a fourth phase of the clock cycle.

29. The apparatus of claim 28, wherein the first, second, third and fourth phases occur in sequential order in each clock cycle.

30. The apparatus of claim 10, wherein the multiple sections are for multiple filter taps of a finite impulse response (FIR) filter and a summing decimator, and wherein a section for filter tap L includes L+N capacitors of equal size determined based on a coefficient for filter tap L, where L is one or greater, and N is a decimation factor greater than one.

31. The apparatus of claim 30, wherein the L+N capacitors in the section for filter tap L are sequentially selected for charging with an input signal, one capacitor in each clock cycle.

32. The apparatus of claim 30, wherein in each clock cycle one capacitor in each section is charged with an input signal during a first phase of the clock cycle and another capacitor in each section is selected for charge sharing and storing a resultant value during a second phase of the clock cycle.

33. The apparatus of claim 32, wherein in every N-th clock cycle N capacitors in each section are selected for charge sharing and providing a value to an output signal during a third phase of the clock cycle and are reset during a fourth phase of the clock cycle.

34. The apparatus of claim 10, further comprising:
an input section comprising
N capacitors of equal size determined based on coefficients for the multiple filter taps, where N is a decimation factor greater than one, and
multiple switches operative to couple the multiple capacitors to the summing node, each switch coupling an associated capacitor to the summing node when enabled and decoupling the associated capacitor from the summing node when disabled, and wherein the multiple sections and the input section implement an infinite impulse response (IIR) filter and a summing decimator.

35. The apparatus of claim 34, wherein the multiple capacitors in the input section are sequentially selected for charging with an input signal, one capacitor in each clock cycle.

36. The apparatus of claim 34, wherein in each clock cycle one capacitor in the input section is charged with an input signal during a first phase of the clock cycle and the one capacitor in the input section and one capacitor in each of the multiple sections are selected for charge sharing during a second phase of the clock cycle.

37. The apparatus of claim 36, wherein in every N-th clock cycle the N capacitors in the input section are selected for charge sharing and providing a value to an output signal during a third phase of the clock cycle and are reset during a fourth phase of the clock cycle.

38. The apparatus of claim 10, wherein the apparatus is an integrated circuit.

39. An apparatus comprising:
a passive switched-capacitor (PSC) filter operative to receive an input signal and provide an output signal, the PSC filter comprising at least one first section for at least one finite impulse response (FIR) tap and at least one second section for at least one infinite impulse response (IIR) tap.

40. The apparatus of claim 39, wherein a first section for FIR tap L, where L is one or greater, comprises
L+1 capacitors of equal size determined based on a coefficient for FIR tap L, and
L+1 switches operative to couple the L+1 capacitors to a summing node.

41. The apparatus of claim 40, wherein the L+1 capacitors in the first section for FIR tap L store L+1 samples of the input signal for L+1 most recent clock cycles.

42. The apparatus of claim 39, wherein a second section for IIR tap L, where L is one or greater, comprises
L capacitors of equal size determined based on a coefficient for IIR tap L, and
L switches operative to couple the L capacitors to a summing node.

43. The apparatus of claim 42, wherein the L capacitors in the second section for IIR tap L store L samples of the output signal for L most recent clock cycles.

44. The apparatus of claim 39, wherein the at least one first section and the at least one second section each comprise at least one capacitor, and wherein one capacitor in each of the at least one first section and one capacitor in each of the at least one second section are selected for charge sharing in each clock cycle.

45. A wireless device comprising:
a passive switched-capacitor (PSC) filter operative to receive an input signal and provide an output signal, the PSC filter comprising
a plurality of capacitors operative to store and share electrical charge, and
a plurality of switches operative to couple the plurality of capacitors to a summing node, each switch coupling an associated capacitor to the summing node when enabled and decoupling the associated capacitor from the summing node when disabled, each capacitor storing a value from the summing node when selected for charging and sharing electrical charge with other capacitors via the summing node when selected for charge sharing; and
a control signal generator operative to generate control signals for the plurality of switches.

46. The wireless device of claim 45, wherein the PSC filter is operative to receive analog input samples for the input signal and provide analog output samples for the output signal, and wherein the wireless device further comprises
an analog-to-digital converter (ADC) operative to digitize the output signal from the PSC filter and provide digital samples.

47. A method of performing filtering, comprising:
enabling a capacitor in each of multiple sections for charging;
charging an input capacitor and the enabled capacitor in each section with an input signal during a first phase of a clock cycle;
selecting another capacitor in each of the multiple sections for charge sharing;
sharing charges on the input capacitor and the selected capacitor in each section during a second phase of the clock cycle; and
providing a value on the input capacitor and the selected capacitor in each section to an output signal during a third phase of the clock cycle.

48. The method of claim 47, further comprising:
resetting the input capacitor and the selected capacitor in each section during a fourth phase of the clock cycle.

49. The method of claim 47, further comprising:
cycling through multiple capacitors in each section and selecting a different capacitor for charging in each clock cycle.

50. An apparatus comprising:
means for enabling a capacitor in each of multiple sections for charging;
means for charging an input capacitor and the enabled capacitor in each section with an input signal during a first phase of a clock cycle;
means for selecting another capacitor in each of the multiple sections for charge sharing;
means for sharing charges on the input capacitor and the selected capacitor in each section during a second phase of the clock cycle; and
means for providing a value on the input capacitor and the selected capacitor in each section to an output signal during a third phase of the clock cycle.

51. The apparatus of claim 50, further comprising:
means for resetting the input capacitor and the selected capacitor in each section during a fourth phase of the clock cycle.

52. A computer program product, comprising:
a computer-readable medium comprising:
code for causing at least one computer to enable a capacitor in each of multiple sections for charging, the enabled capacitor in each section and an input capacitor being charged with an input signal during a first phase of a clock cycle,
code for causing at least one computer to select another capacitor in each of the multiple sections for charge sharing, the selected capacitor in each section and the input capacitor sharing charges during a second phase of the clock cycle, and
code for causing at least one computer to enable a switch to provide a value on the input capacitor and the selected capacitor in each section to an output signal during a third phase of the clock cycle.

53. A method of performing filtering, comprising:
charging an input capacitor with an input signal during a first phase of a clock cycle;
selecting a capacitor in each of multiple sections for charge sharing;
sharing charges on the input capacitor and the selected capacitor in each section during a second phase of the clock cycle to obtain a value;
storing the value on the selected capacitor in each section at end of the second phase; and
providing the value on the input capacitor to an output signal during a third phase of the clock cycle.

54. The method of claim 53, further comprising:
resetting the input capacitor during a fourth phase of the clock cycle.

55. The method of claim 53, further comprising:
cycling through at least one capacitor in each section and selecting a different capacitor for charge sharing in each clock cycle.

56. An apparatus comprising:
means for charging an input capacitor with an input signal during a first phase of a clock cycle;
means for selecting a capacitor in each of multiple sections for charge sharing;
means for sharing charges on the input capacitor and the selected capacitor in each section during a second phase of the clock cycle to obtain a value;
means for storing the value on the selected capacitor in each section at end of the second phase; and
means for providing the value on the input capacitor to an output signal during a third phase of the clock cycle.

57. The apparatus of claim 56, further comprising:
means for resetting the input capacitor during a fourth phase of the clock cycle.
